(19) United States
(12) Patent Application Publication
(10) Pub. No.: US 2025/0248051 A1
(43) Pub. Date: Jul. 31, 2025

(54) SEMICONDUCTOR DEVICE

(71) Applicant: Samsung Electronics Co., Ltd., Suwon-si (KR)

(72) Inventors: Seungmuk KIM, Suwon-si (KR); Hui-Jung KIM, Suwon-si (KR); Kiseok LEE, Suwon-si (KR); Keunnam KIM, Suwon-si (KR); Yong Kwan KIM, Suwon-si (KR); Sangho LEE, Suwon-si (KR); Jihun LEE, Suwon-si (KR)

(73) Assignee: Samsung Electronics Co., Ltd., Suwon-si (KR)

(21) Appl. No.: 18/956,536

(22) Filed: Nov. 22, 2024

(30) Foreign Application Priority Data
Jan. 25, 2024 (KR) 10-2024-0011686

(51) Int. Cl. H10B 80/00; H01L 23/00; H01L 25/065; H01L 25/18

(52) U.S. Cl. CPC H10B 80/00; H01L 24/08; H01L 25/0657; H01L 25/18; H01L 2224/08145; H01L 2225/06541; H01L 2924/1431; H01L 2924/1436

(57) ABSTRACT

A semiconductor device may include a cell chip and a core/peripheral chip on the cell chip. The cell chip may include a first semiconductor substrate, a first device layer disposed on the first semiconductor substrate, a bottom electrode disposed on the first device layer, a dielectric layer conformally covering a top surface of the first device layer and the bottom electrode, a top electrode disposed on the bottom electrode and spaced apart from the bottom electrode by the dielectric layer, an insulating layer provided on the first device layer to cover the top electrode, and a first contact vertically penetrating one of the first semiconductor substrate or the insulating layer and connected to the top electrode. The top electrode may include a semiconductor layer and a metal layer that are stacked, and the first contact may be in contact with the metal layer.

### CROSS-REFERENCE TO RELATED APPLICATIONS

This U.S. non-provisional patent application claims priority under 35 U.S.C. § 119 to Korean Patent Application No. 10-2024-0011686, filed on Jan. 25, 2024, in the Korean Intellectual Property Office, the entire contents of which are hereby incorporated by reference.

### BACKGROUND

The present disclosure relates to semiconductor devices and methods of fabricating the same.

A semiconductor device may include a plurality of circuit regions provided therein. For example, the semiconductor device has a cell array region for memory elements and a peripheral region, in which circuits for driving the memory elements and performing data input/output operations are provided. Various devices are disposed in regions, respectively, and here, the electrical characteristics required for the devices may vary from region to region. Meanwhile, as the integration density of the semiconductor device increases, it is necessary to form more circuits within a limited chip area. Thus, it is necessary to reduce a form factor of the semiconductor device while optimizing the devices in each region in order to improve reliability of the semiconductor device.

Due to the recent increasing demand for electronic devices with a fast speed and/or low power consumption, the semiconductor device requires a fast operating speed and/or a low operating voltage. To satisfy these requirements, it is necessary to increase an integration density of the semiconductor device. Many studies are being conducted to increase an operation speed and reliability of semiconductor device.

### SUMMARY

Some example embodiments of the inventive concepts provide semiconductor devices with improved electrical characteristics.

Some example embodiments of the inventive concepts provide semiconductor devices with a reduced size.

According to an example embodiment of the inventive concepts, a semiconductor device may include a cell chip and a core/peripheral chip on the cell chip. The cell chip may include a first semiconductor substrate, a first device layer on the first semiconductor substrate, a bottom electrode on the first device layer, a dielectric layer conformally covering a top surface of the first device layer and the bottom electrode, a top electrode on the bottom electrode and spaced apart from the bottom electrode by the dielectric layer, an insulating layer on the first device layer and covering the top electrode, and a first contact vertically penetrating one of the first semiconductor substrate or the insulating layer and connected to the top electrode. The top electrode may include a semiconductor layer and a metal layer that are stacked, and the first contact may be in contact with the metal layer.

According to an example embodiment of the inventive concepts, a semiconductor device may include a cell chip and a core/peripheral chip on the cell chip. The cell chip may include a first device layer, a capacitor on the first device layer, an insulating layer on the first device layer and covering the capacitor, a first contact vertically penetrating the first device layer and being in contact with the capacitor, an interconnection pattern being apart from the capacitor and on the first device layer, and a second contact vertically penetrating the first device layer and being in contact with the interconnection pattern. The capacitor may include a bottom electrode on a top surface of the first device layer, a dielectric layer covering the bottom electrode and being on the first device layer, a top electrode covering the dielectric layer, and an additional electrode on a surface of the top electrode. The additional electrode may have an electric conductivity that is higher than that of the top electrode. The interconnection pattern may include a first pattern on the top surface of the first device layer and a second pattern covering a surface of the first pattern. The first pattern may include the same material as the top electrode, and the second pattern may include the same material as the additional electrode.

According to an example embodiment of the inventive concepts, a semiconductor device may include a first semiconductor substrate, a device layer on the first semiconductor substrate, an interlayer insulating layer on the first semiconductor substrate and covering the device layer, a second semiconductor substrate on the interlayer insulating layer, a device isolation pattern defining an active region in the second semiconductor substrate, a word line in the second semiconductor substrate and crossing the active region, a first impurity region in the active region and at one side of the word line, a second impurity region in the active region and at an opposite side of the word line, a bit line connected to the first impurity region and crossing the second semiconductor substrate, a landing pad on the second impurity region, a storage node contact connecting the landing pad to the second impurity region, a capacitor on and connected to the landing pad, and a contact vertically penetrating the second semiconductor substrate and the interlayer insulating layer and connecting the device layer to the capacitor. The capacitor may include a bottom electrode, a top electrode conformally covering the bottom electrode, a dielectric layer between the bottom electrode and the top electrode, and an additional electrode conformally covering the top electrode. An electric conductivity of the additional electrode may be higher than an electric conductivity of the top electrode, and the contact may penetrate the top electrode and may be in contact with the additional electrode.

### BRIEF DESCRIPTION OF THE DRAWINGS

FIG. 1 is a block diagram illustrating a semiconductor device according to an example embodiment of the inventive concepts.

FIGS. 2 and 3 are perspective views illustrating a semiconductor device according to an example embodiment of the inventive concepts.

FIG. 4 is a sectional view illustrating a semiconductor device according to an example embodiment of the inventive concepts.

FIGS. 5 to 7 are enlarged sectional views illustrating a portion ‘A’ of FIG. 4 according to some example embodiment.

FIGS. 8 to 15 are sectional views illustrating a semiconductor device according to an example embodiment of the inventive concepts.

FIGS. 16 and 17 are sectional views illustrating a semiconductor package including a semiconductor device according to an example embodiment of the inventive concepts.

FIGS. 18 to 22 are sectional views illustrating a method of fabricating a semiconductor device according to an example embodiment of the inventive concepts.

### DETAILED DESCRIPTION

Example embodiments of the inventive concepts will now be described more fully with reference to the accompanying drawings, in which example embodiments are shown.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Expressions such as “one of” and “at least one of,” when preceding a list of elements, modify the entire list of elements and do not modify the individual elements of the list. For example, an expression such as “at least one of A, B, and C” or “at least one selected from the group consisting of A, B, and C” may be interpreted as only A, only B, only C, or any combination of two or more of A, B, and C, such as A, B, and C, A and B, B and C, and A and C.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

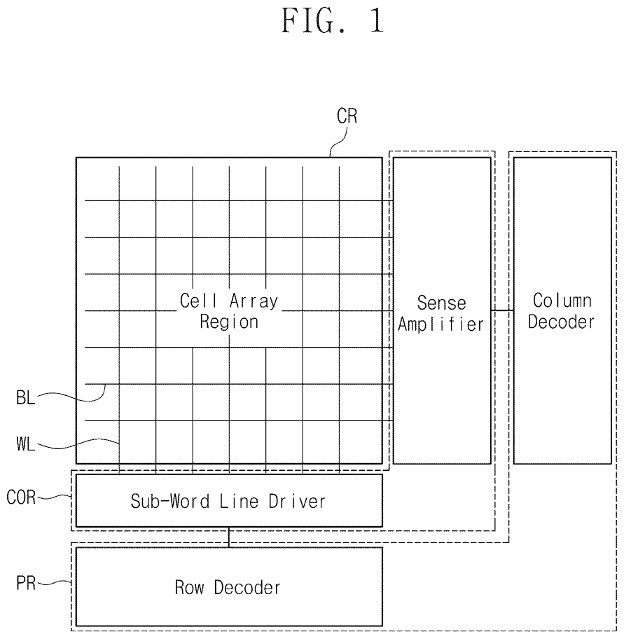

FIG. 1 is a block diagram illustrating a semiconductor device according to an example embodiment of the inventive concepts.

Referring to FIG. 1, the semiconductor device in the present example embodiment may be, for example, a dynamic access memory (DRAM) device. The semiconductor device may include a cell array region CR. Word lines WL and bit lines BL, which cross each other, may be disposed in the cell array region CR.

A core region COR may be disposed near the cell array region CR. A sub-word line driver and a sensing amplifier may be disposed in the core region COR. The sub-word line driver may be configured to select one of the word lines, in response to a row address signal or a refresh address signal. In the case where an amount of charges stored in a cell capacitor of a selected memory cell is very small, it may be difficult to directly produce a digital signal, which will be output to the outside, from the stored charges, and in this situation, the sensing amplifier may be configured to execute the function of amplifying a signal produced by a small charge amount.

A peripheral circuit region PR may be disposed near the core region COR. A row decoder and a column decoder may be disposed in the peripheral circuit region PR. A structure including the core region COR and the peripheral circuit region PR may be referred to as a logic region. The row decoder may be configured to decode the row address signal or the refresh address signal. The column decoder may be configured to decode a column address signal and execute an operation of selecting the bit line BL, based on the decoded column address signal.

The core region COR and the peripheral circuit region PR may constitute a logic region for driving the cell array region CR.

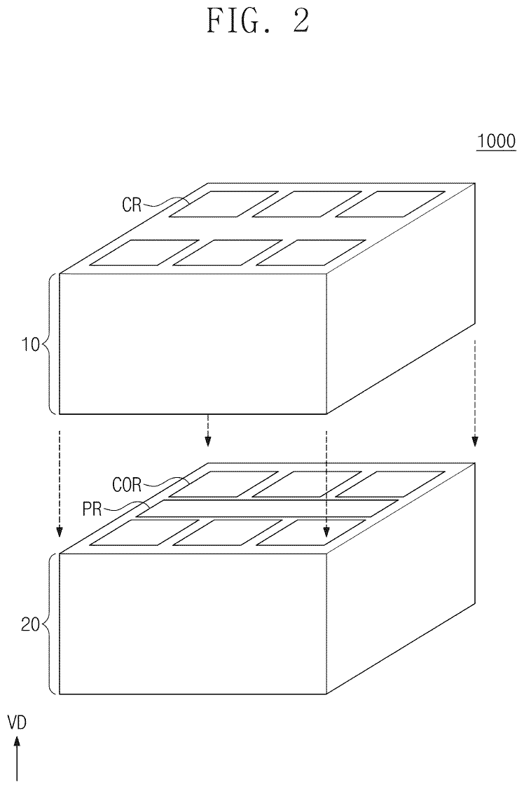

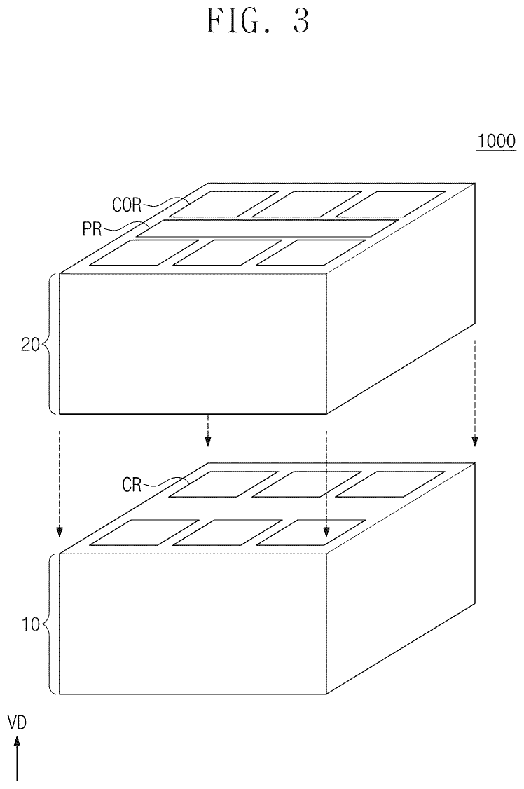

FIGS. 2 and 3 are perspective view illustrating a semiconductor device according to an example embodiment of the inventive concepts.

Referring to FIGS. 2 and 3, a memory chip 1000 may include a core/peripheral chip 20 and a cell chip 10, which is disposed in a vertical direction VD. The core/peripheral chip 20 and the cell chip 10 may vertically overlap each other. The cell chip 10 may be stacked on the core/peripheral chip 20, as shown in FIG. 2. The core/peripheral chip 20 may be stacked on the cell chip 10, as shown in FIG. 3.

The core/peripheral chip 20 may include core regions COR and a peripheral region PR, when viewed in a plan view. The core regions COR and the peripheral circuit region PR may be adjacent to each other in a horizontal direction. Each of the core regions COR may include a core bank, and the core bank may include core circuits (e.g., a sub-word line driver, a sensing amplifier, a row decoder, a column decoder, and a read/write circuit). The peripheral circuit region PR may include peripheral circuits (e.g., a timing register, an address register, a data input register, a data output register, and a data input/output terminal). The core regions COR and the peripheral circuit region PR may include a core/peripheral transistor 210, which will be described below.

The cell chip 10 may include the cell array regions CR, when viewed in a plan view. The cell array regions CR may be adjacent to each other in a horizontal direction. Each of the cell array regions CR may vertically overlap at least a portion of each of the core regions COR. Each of the cell array regions CR may include a memory cell layer 110 to be described below, and the memory cell layer 110 may be configured to store data.

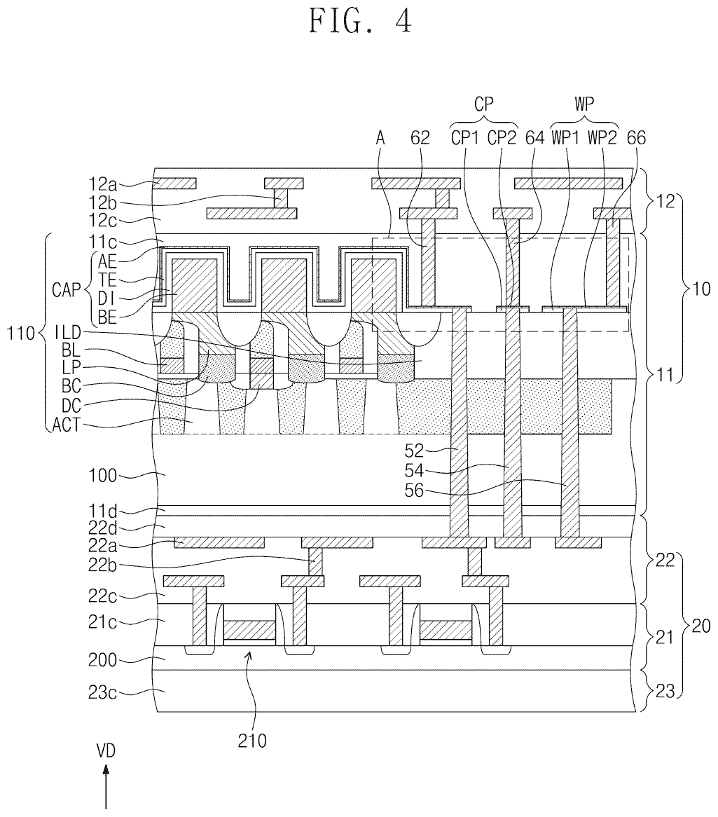

FIG. 4 is a sectional view illustrating a semiconductor device according to an example embodiment of the inventive concepts. FIGS. 5 to 7 are enlarged sectional views illustrating a portion ‘A’ of FIG. 4.

Referring to FIG. 4, the core/peripheral chip 20 may include a driving layer 21, a core/peripheral interconnection layer 22, and a rear interconnection layer 23.

The driving layer 21 may be a device layer including a semiconductor device. In an example embodiment, the driving layer 21 may include a core/peripheral semiconductor layer 200 and a core/peripheral transistor 210 on the core/peripheral semiconductor layer 200. The core/peripheral semiconductor layer 200 may include a top surface and a bottom surface, which are opposite to each other in the vertical direction VD. The top surface of the core/peripheral semiconductor layer 200 may be a front surface of the core/peripheral semiconductor layer 200, and the core/peripheral transistor 210 may be formed on the front surface of the core/peripheral semiconductor layer 200. The bottom surface of the core/peripheral semiconductor layer 200 may be a rear surface of the core/peripheral semiconductor layer 200. In other words, the top surface of the core/peripheral semiconductor layer 200 may be an active surface of a cell semiconductor layer 100, and a bottom surface of the cell semiconductor layer 100 may be an inactive surface of the core/peripheral semiconductor layer 200.

The core/peripheral semiconductor layer 200 may include a semiconductor material. In an example embodiment, the core/peripheral semiconductor layer 200 may be a semiconductor substrate (e.g., a single-crystalline silicon substrate, a Si—Ge substrate, or a silicon-on-insulator (SOI) substrate) that is formed of a semiconductor material. As another example, the core/peripheral semiconductor layer 200 may be an epitaxial layer including a semiconductor material.

The core/peripheral transistor 210 may be used as a part of a core circuit, a peripheral circuit, and a neural processing unit (NPU). In an example embodiment, as shown in FIG. 4, the core/peripheral transistor 210 may include source and drain patterns, which are provided in an upper portion of the core/peripheral semiconductor layer 200, a gate electrode, which is disposed on the front surface of the core/peripheral semiconductor layer 200 between the source and drain patterns, and a gate insulating layer, which is interposed between the core/peripheral semiconductor layer 200 and the gate electrode. The core/peripheral transistor 210 may be illustrated as a planar-type transistor, as shown in FIG. 4, but transistors of various structures may be used as the core/peripheral transistor 210. In an example embodiment, a plurality of core/peripheral transistors 210 may be provided to constitute an integrated circuit. The core/peripheral transistors 210 may constitute the core regions COR or the peripheral circuit region PR described with reference to FIGS. 2 and 3.

The driving layer 21 may further include a first interlayer insulating layer 21c. The first interlayer insulating layer 21c may be provided on the core/peripheral semiconductor layer 200 to cover the core/peripheral transistor 210. In FIG. 4, the first interlayer insulating layer 21c is illustrated to expose a top surface of the core/peripheral transistor 210 near a top surface thereof, but example embodiments of the inventive concepts are not limited to this example. The first interlayer insulating layer 21c may be formed of or include at least one of SiO, SiN, SiON, SiCN, or porous insulating materials and may have a single- or multi-layered structure.

The core/peripheral interconnection layer 22 may be disposed on the driving layer 21. The core/peripheral interconnection layer 22 may include core/peripheral circuit lines 22a, core/peripheral contact plugs 22b, which are used to electrically connect the core/peripheral transistor 210 to the core/peripheral circuit lines 22a, and a second interlayer insulating layer 22c. The core/peripheral circuit lines 22a and the core/peripheral contact plugs 22b may be collectively referred to as core/peripheral interconnection patterns 22a and 22b.

The driving layer 21 may be covered with the second interlayer insulating layer 22c. The second interlayer insulating layer 22c may be formed of or include at least one of SiO, SiN, SiON, SiCN, or porous insulating materials and may have a single- or multi-layered structure.

Interconnection lines, which are electrically connected to the core/peripheral transistor 210, may be disposed in the second interlayer insulating layer 22c. The interconnection lines may include the core/peripheral interconnection patterns 22a and 22b, which are buried in the second interlayer insulating layer 22c. For example, the core/peripheral interconnection patterns 22a and 22b may include the core/peripheral circuit lines 22a for horizontal interconnection and the core/peripheral contact plugs 22b for vertical interconnection. The core/peripheral interconnection patterns 22a and 22b may be provided to vertically penetrate the second interlayer insulating layer 22c and may be connected to the driving layer 21 (e.g., one of source, drain, and gate electrodes of the core/peripheral transistor 210). The core/peripheral interconnection patterns 22a and 22b may be located between top and bottom surfaces of the second interlayer insulating layer 22c. The core/peripheral interconnection patterns 22a and 22b may be formed of or include, for example, copper (Cu) or tungsten (W).

The core/peripheral interconnection patterns 22a and 22b may have a damascene structure. For example, the core/peripheral interconnection patterns 22a and 22b may include a head portion and a tail portion, which are connected to form a single object (e.g., a single integral body). The core/peripheral circuit lines 22a may be the head portions of the core/peripheral interconnection patterns 22a and 22b, and the core/peripheral contact plugs 22b may be the tail portions of the core/peripheral interconnection patterns 22a and 22b. The core/peripheral circuit lines 22a may be a wire portion or a pad portion, which is used for a horizontal extension of the interconnection line in the core/peripheral interconnection layer 22. At least a portion of the core/peripheral circuit lines 22a may be exposed to the outside through a top surface of the second interlayer insulating layer 22c. In some example embodiments, the core/peripheral circuit lines 22a may be buried in the second interlayer insulating layer 22c and may not be exposed to the outside through the top surface of the second interlayer insulating layer 22c. The core/peripheral contact plugs 22b may be via portions vertically connecting the interconnection lines in the core/peripheral interconnection layer 22 to each other. The tail portion may be extended from a bottom surface of the head portion and may be coupled to a top surface of another one of the core/peripheral circuit lines 22a thereunder or the core/peripheral transistor 210.

The rear interconnection layer 23 may be disposed below the core/peripheral semiconductor layer 200. For example, the rear interconnection layer 23 may be disposed on the rear surface of the core/peripheral semiconductor layer 200 (e.g., the bottom surface of the core/peripheral semiconductor layer 200). The rear interconnection layer 23 may include a third interlayer insulating layer 23c.

The rear surface of the core/peripheral semiconductor layer 200 may be covered with the third interlayer insulating layer 23c. The third interlayer insulating layer 23c may be formed of or include at least one of SiO, SiN, SiON, SiCN, or porous insulating materials and may have a single- or multi-layered structure.

A first passivation layer 22d may be provided on the second interlayer insulating layer 22c of the core/peripheral interconnection layer 22. The first passivation layer 22d may cover the second interlayer insulating layer 22c and the core/peripheral interconnection patterns 22a and 22b. The first passivation layer 22d may be formed of or include at least one of SiO, SiN, SiON, SiCN, or porous insulating materials and may have a single- or multi-layered structure.

The cell chip 10 may be disposed on the core/peripheral chip 20. The cell chip 10 may include a data storage layer 11 and a cell interconnection layer 12. The data storage layer 11 may be a device layer including a semiconductor device. For example, the data storage layer 11 may include the cell semiconductor layer 100 and the memory cell layer 110. The cell semiconductor layer 100 may include a top surface and a bottom surface, which are opposite to each other in the vertical direction VD. The top surface of the cell semiconductor layer 100 may be a front surface of the cell semiconductor layer 100, and the memory cell layer 110 may be formed on the front surface of the cell semiconductor layer 100. The bottom surface of the cell semiconductor layer 100 may be a rear surface of the cell semiconductor layer 100. In other words, the top surface of the cell semiconductor layer 100 may be an active surface of the cell semiconductor layer 100, and the bottom surface of the cell semiconductor layer 100 may be an inactive surface of the cell semiconductor layer 100.

The cell semiconductor layer 100 may include a semiconductor material. In an example embodiment, the cell semiconductor layer 100 may be a semiconductor substrate (e.g., a single-crystalline silicon substrate, a Si—Ge substrate, or a silicon-on-insulator (SOI) substrate) that is formed of a semiconductor material. In another example embodiment, the cell semiconductor layer 100 may be a semiconductor epitaxial layer including a semiconductor material.

A second passivation layer 11d may be provided below the cell semiconductor layer 100. The second passivation layer 11d may cover the bottom surface of the cell semiconductor layer 100. The second passivation layer 11d may be formed of or include at least one of SiO, SiN, SiON, or SiCN.

The memory cell layer 110 may be provided on the cell semiconductor layer 100. The memory cell layer 110 may include at least one of various types of memory semiconductor devices. As an example, the memory cell layer 110 may include a two-dimensional memory device (e.g., DRAM devices of a buried channel array transistor (BCAT) type or a vertical channel transistor (VCT) type). As another example, the memory cell layer 110 may include a three-dimensional memory device, such as a vertically-stacked DRAM (VS DRAM) device, a three-dimensional ferroelectric FET (3D FeFET) device, and a 3D monolithic device. For example, the memory cell layer 110 may include a BCAT-type DRAM device, which includes an active region ACT, a bit line node contact DC, a bit line BL, a storage node contact BC, and a landing pad LP, as shown in FIG. 4. Here, a word line (not shown) may be provided below a top surface of the active region ACT to cross the active region ACT. The memory cell layer 110 may constitute the cell array regions CR described with reference to FIGS. 2 and 3 and may be used to store data therein.

For example, device isolation patterns may be disposed on the cell semiconductor layer 100 to define the active regions ACT. Each of the active regions ACT may be a bar-shaped pattern extending in a specific direction, when viewed in a plan view. The word lines may be disposed to cross the active regions ACT. The word lines may be disposed in grooves, which are formed in the device isolation patterns and the active regions ACT. A first impurity region may be disposed in each of the active regions ACT between a pair of the word lines, and a pair of second impurity regions may be disposed in opposite edge regions of each of the active regions ACT, respectively. A first interlayer insulating pattern (not shown) may be disposed on the cell semiconductor layer 100. The first interlayer insulating pattern may be formed to cover both of end portions of a pair of the active regions ACT, which are adjacent to each other. The bit lines BL may be disposed on the first interlayer insulating pattern. The bit lines BL may be disposed to cross the word lines. The bit line node contact DC may electrically connect the first impurity region to the bit line BL. The storage node contacts BC may be disposed between an adjacent pair of the bit lines BL. The storage node contacts BC may be connected to the second impurity regions. The landing pads LP may be disposed on the storage node contacts BC. The landing pads LP may be connected to the second impurity regions through the storage node contacts BC. A pad separation pattern may be interposed between the landing pads LP. A second interlayer insulating pattern ILD may be disposed on the cell semiconductor layer 100. The second interlayer insulating pattern ILD may cover the landing pad LP, the storage node contacts BC, the bit lines BL, and the bit line node contact DC, and here, a top surface of the landing pad LP may be exposed to the outside through a top surface of the second interlayer insulating pattern ILD.

In some example embodiments, the memory cell layer 110 may include a VCT-type DRAM device, which includes a bit line, a channel pattern, and a word line. Here, the channel pattern may be formed of or include at least one of single-crystalline silicon, poly-crystalline silicon, oxide semiconductor materials (e.g., InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, or InₓGa_{y}O), two-dimensional materials (e.g., graphene), or a transition metal dichalcogenide (TMD) including a transition metal element (e.g., Mo, W, V, Nb, Ta, or Ti) and a chalcogen element (S, Se, or Te).

The memory cell layer 110 may further include a capacitor CAP. The capacitor CAP may be provided on the second interlayer insulating pattern ILD. The capacitor CAP may include a bottom electrode BE, a dielectric layer DI, a top electrode TE, and an additional electrode AE.

Referring to FIGS. 4 and 5, the bottom electrodes BE may be disposed on the landing pads LP. The bottom electrodes BE may be in contact with the landing pads LP, respectively. The bottom electrodes BE may have a pillar shape. For example, each of the bottom electrodes BE may be a plug-shaped pattern with a circular cross-section. The bottom electrodes BE may be arranged in a honeycomb shape, when viewed in a plan view. In some example embodiments, the bottom electrodes BE may be arranged to form a grid shape, when viewed in a plan view. The planar arrangement of the bottom electrodes BE may be variously changed, as desired. The bottom electrodes BE may include a conductive material. In an example embodiment, the bottom electrodes BE may be formed of or include at least one of a semiconductor material, a metallic material, or a conductive oxide material. As an example, the bottom electrodes BE may be formed of or include at least one of a metallic material, a metal oxide material, or doped polysilicon. As another example, the bottom electrodes BE may be formed of or include tin oxide (SnO₂) or strontium ruthenate (SrRuO₃) that is doped with tantalum (Ta).

Although not shown, supporting patterns (not shown) may be provided between the bottom electrodes BE, which are adjacent to each other. The supporting patterns may connect the adjacent ones of the bottom electrodes BE to each other, and thus, the adjacent ones of the bottom electrodes BE may be supported by the supporting patterns. In an example embodiment, the supporting patterns may not be provided.

The dielectric layer DI may be disposed on the bottom electrodes BE. The dielectric layer DI may conformally cover the bottom electrodes BE. The dielectric layer DI may cover the bottom electrodes BE with a uniform thickness. In the case where the supporting pattern is provided between the bottom electrodes BE, the dielectric layer DI may cover the supporting pattern with a uniform thickness. The dielectric layer DI may include an insulating material. The dielectric layer DI may include a high-k dielectric material. In an example embodiment, the dielectric layer DI may be formed of or include at least one of metal oxide materials (e.g., aluminum oxide (Al₂O₃)) and may have a single- or multi-layered structure.

The top electrode TE may be disposed on the dielectric layer DI. The top electrode TE may conformally cover the dielectric layer DI. The top electrode TE may cover the dielectric layer DI with a uniform thickness. The top electrode TE may include a semiconductor material. For example, the top electrode TE may be formed of or include SiGe or doped poly silicon and may have a single- or multi-layered structure.

The additional electrode AE may be disposed on the top electrode TE. The additional electrode AE may conformally cover the top electrode TE. In other words, the top electrode TE may be interposed between the dielectric layer DI and the additional electrode AE. An electric conductivity of the additional electrode AE may be higher than an electric conductivity of the top electrode TE. The additional electrode AE may be formed of or include at least one of a metallic material or a conductive metal nitride material. For example, the additional electrode AE may be formed of or include at least one of W, WN, Ti, TiN, Ta, or TaN.

The dielectric layer DI, the top electrode TE, and the additional electrode AE may be sequentially stacked to form a stacking structure, and here, the stacking structure may conformally cover the bottom electrodes BE. The dielectric layer DI, the top electrode TE, and the additional electrode AE may be provided to cover the bottom electrodes BE and may be horizontally extended along the top surface of the second interlayer insulating pattern ILD, near the bottom electrodes BE.

The bottom electrodes BE may be electrodes of the capacitor CAP, which are connected to the landing pads LP, and the top electrode TE and the additional electrode AE may constitute relative electrodes of the bottom electrodes BE. That is, the top electrode TE and the additional electrode AE may be used as a top electrode of the capacitor CAP. Hereinafter, the top electrode TE and the additional electrode AE constituting the top electrode of the capacitor CAP may be referred to as relative electrodes TE and AE.

According to an example embodiment of the inventive concepts, the additional electrode AE formed of a metallic material may be in contact with the entire exposed surface of the top electrode TE formed of a semiconductor material. Thus, it may be possible to lower a total electric resistance of the relative electrodes TE and AE of the capacitor CAP. In addition, it may be possible to increase a transmission speed of an electric signal that is transmitted to each portion of the top electrode TE along the additional electrode AE. This may make it possible to realize the semiconductor device with improved electrical characteristics.

Furthermore, because the total electric resistance of the relative electrodes TE and AE is lowered due to the presence of the additional electrode AE, there may be no need to thickly form the top electrode TE in order to lower an electric resistance of the top electrode TE. That is, the top electrode TE may be provided to a thin thickness, and moreover, the additional electrode AE with a low electric resistance may also be provided to a thin thickness. That is, it may be possible to reduce a thickness and an electric resistance of the relative electrodes TE and AE and to reduce the height of the capacitor CAP and the size of the semiconductor device.

Referring back to FIG. 4, the capacitor CAP may be covered with a fourth interlayer insulating layer 11c. The fourth interlayer insulating layer 11c may be provided on the second interlayer insulating pattern ILD to bury the capacitor CAP. The fourth interlayer insulating layer 11c may be formed of or include at least one of SiO, SiN, SiON, SiCN, or porous insulating materials and may have a single- or multi-layered structure.

The cell interconnection layer 12 may be disposed on the data storage layer 11. The cell interconnection layer 12 may include cell circuit lines 12a, cell contact plugs 12b, which are used to electrically connect the memory cell layer 110 to the cell circuit lines 12a, and a fifth interlayer insulating layer 12c. The cell circuit lines 12a and the cell contact plugs 12b may be collectively referred to as cell interconnection patterns.

The memory cell layer 110 may be covered with the fifth interlayer insulating layer 12c. The fifth interlayer insulating layer 12c may be formed of or include at least one of SiO, SiN, SiON, SiCN, or porous insulating materials and may have a single- or multi-layered structure.

Interconnection lines, which are electrically connected to the memory cell layer 110, may be disposed in the fifth interlayer insulating layer 12c. The interconnection lines may include the cell interconnection patterns 12a and 12b, which are buried in the fifth interlayer insulating layer 12c. For example, the cell interconnection patterns 12a and 12b may include the cell circuit lines 12a, which are used for horizontal interconnection, and the cell contact plugs 12b, which are used for vertical interconnection. The cell interconnection patterns 12a and 12b may be located between top and bottom surfaces of the fifth interlayer insulating layer 12c. The cell interconnection patterns 12a and 12b may be formed of or include, for example, copper (Cu) or tungsten (W).

The cell interconnection patterns 12a and 12b may have a damascene structure. For example, the cell interconnection patterns 12a and 12b may include a head portion and a tail portion, which are connected to form a single object. The cell circuit lines 12a may be the head portions of the cell interconnection patterns 12a and 12b, and the cell contact plugs 12b may be the tail portions of the cell interconnection patterns 12a and 12b. The head portions of the cell interconnection patterns 12a and 12b (e.g., the cell circuit lines 12a) may be wire portions or pad portions, which are used to horizontally expand the interconnection line in the cell interconnection layer 12. The cell circuit lines 12a may not be exposed to the outside through the top surface of the fifth interlayer insulating layer 12c. The tail portions of the cell interconnection patterns 12a and 12b (e.g., the cell contact plugs 12b) may be via portions which are used to vertically connect the interconnection lines in the cell interconnection layer 12 to each other. The tail portion may be extended from the bottom surface of the head portion and may be coupled to a top surface of another one of the cell circuit lines 12a thereunder.

The cell interconnection patterns 12a and 12b may be electrically connected to the capacitor CAP. For example, a first contact 62 may be provided in the cell chip 10. The first contact 62 may vertically penetrate the fourth and fifth interlayer insulating layers 11c and 12c, on the capacitor CAP or near the capacitor CAP. An end portion of the first contact 62 may be coupled to the cell circuit lines 12a, in the fifth interlayer insulating layer 12c. An opposite end portion of the first contact 62 may be coupled to the relative electrodes TE and AE of the capacitor CAP (in particular, the additional electrode AE), in the fourth interlayer insulating layer 11c. The capacitor CAP may be configured to send or receive electrical signals through the first contact 62. The first contact 62 may be formed of or include at least one metallic material (e.g., copper (Cu) or tungsten (W)).

The cell chip 10 may be disposed on the core/peripheral chip 20. The cell chip 10 may be in direct contact with the core/peripheral chip 20.

At an interface between the cell chip 10 and the core/peripheral chip 20, the second passivation layer 11d of the cell chip 10 may be bonded to the first passivation layer 22d of the core/peripheral chip 20. Here, the first and second passivation layers 22d and 11d may form a hybrid bonding structure of oxide, nitride, or oxynitride. In the present specification, the hybrid bonding structure may mean a bonding structure that is formed by two materials, which are of the same kind and are fused at an interface therebetween. For example, the first and second passivation layers 22d and 11d, which are bonded to each other, may have a continuous structure, and there may be no visible interface between the first and second passivation layers 22d and 11d. For example, the first and second passivation layers 22d and 11d may be formed of the same material, and in this case, there may be no interface between the first and second passivation layers 22d and 11d. In other words, the first and second passivation layers 22d and 11d may be provided as a single object (e.g., an single integral body). For example, the first and second passivation layers 22d and 11d may be bonded to form a single object. However, example embodiments of the inventive concepts are not limited to this example. The first and second passivation layers 22d and 11d may be formed of different materials from each other. The first and second passivation layers 22d and 11d may not have a continuous structure, and in this case, there may be a visible interface between the first and second passivation layers 22d and 11d. The first and second passivation layers 22d and 11d may not be bonded to each other, and each of the first and second passivation layers 22d and 11d may be provided as an individual element.

A second contact 52 may be provided in the cell chip 10. The second contact 52 may be provided to vertically penetrate the second interlayer insulating pattern ILD, the cell semiconductor layer 100, the second passivation layer 11d, and the first passivation layer 22d. An end portion of the second contact 52 may be coupled to the core/peripheral circuit lines 22a, in the second interlayer insulating layer 22c. An opposite end portion of the second contact 52 may be coupled to the relative electrodes TE and AE (e.g., the additional electrode AE) of the capacitor CAP in the fourth interlayer insulating layer 11c. Here, the second contact 52 may be provided to penetrate the top electrode TE and may be directly connected to the additional electrode AE. The capacitor CAP may be configured to send or receive electrical signals through the second contact 52. The capacitor CAP may be electrically connected to the core/peripheral transistor 210 through the second contact 52. The second contact 52 may be formed of or include at least one metallic material (e.g., copper (Cu) or tungsten (W)).

The memory cell layer 110 may further include a contact connection pattern CP. The contact connection pattern CP may be disposed on the second interlayer insulating pattern ILD. The contact connection pattern CP may be horizontally spaced apart from the capacitor CAP. The contact connection pattern CP may be covered with the fourth interlayer insulating layer 11c, on the second interlayer insulating pattern ILD. The contact connection pattern CP may include a first contact connection pattern CP1 and a second contact connection pattern CP2.

The first contact connection pattern CP1 may be disposed on the second interlayer insulating pattern ILD. The first contact connection pattern CP1 may be an element that is formed through the same process as that for the top electrode TE. A thickness of the first contact connection pattern CP1 may be equal to a thickness of the top electrode TE. The first contact connection pattern CP1 may be formed of the same material as the top electrode TE. The first contact connection pattern CP1 may include a semiconductor material. For example, the first contact connection pattern CP1 may be formed of or include SiGe or doped poly silicon and may have a single- or multi-layered structure.

The second contact connection pattern CP2 may be disposed on the first contact connection pattern CP1. In other words, the first contact connection pattern CP1 may be interposed between the second interlayer insulating pattern ILD and the second contact connection pattern CP2. The second contact connection pattern CP2 may be an element that is formed through the same process as that for the additional electrode AE. A thickness of the second contact connection pattern CP2 may be equal to a thickness of the additional electrode AE. The second contact connection pattern CP2 may be formed of the same material as the additional electrode AE. An electric conductivity of the second contact connection pattern CP2 may be higher than an electric conductivity of the first contact connection pattern CP1. The second contact connection pattern CP2 may be formed of or include at least one of a metallic material or a conductive metal nitride material. For example, the second contact connection pattern CP2 may be formed of or include at least one of W, WN, Ti, TiN, Ta, or TaN.

The cell interconnection patterns 12a and 12b may be electrically connected to the contact connection pattern CP. For example, a third contact 64 may be provided in the cell chip 10. The third contact 64 may vertically penetrate the fourth and fifth interlayer insulating layers 11c and 12c, near the capacitor CAP. An end portion of the third contact 64 may be coupled to the cell circuit lines 12a in the fifth interlayer insulating layer 12c. An opposite end portion of the third contact 64 may be coupled to the contact connection pattern CP (e.g., the second contact connection pattern CP2) in the fourth interlayer insulating layer 11c. The first contact 62 may be formed of or include at least one metallic material (e.g., copper (Cu) or tungsten (W)).

A fourth contact 54 may be provided in the cell chip 10. The fourth contact 54 may be provided to vertically penetrate the second interlayer insulating pattern ILD, the cell semiconductor layer 100, the second passivation layer 11d, and the first passivation layer 22d. An end portion of the fourth contact 54 may be coupled to the core/peripheral circuit lines 22a in the second interlayer insulating layer 22c. An opposite end portion of the fourth contact 54 may be coupled to the contact connection pattern CP (e.g., the second contact connection pattern CP2) in the fourth interlayer insulating layer 11c. Here, the fourth contact 54 may be provided to penetrate the first contact connection pattern CP1 and may be directly connected to the second contact connection pattern CP2. The fourth contact 54 may be formed of or include at least one metallic material (e.g., copper (Cu) or tungsten (W)).

The contact connection pattern CP may be an intermediate pad connecting the fourth contact 54, which is connected to the core/peripheral circuit lines 22a in the core/peripheral chip 20, to the third contact 64, which is connected to the cell circuit lines 12a in the cell chip 10.

According to an example embodiment of the inventive concepts, because the third contact 64 and the fourth contact 54 are connected to each other through the second contact connection pattern CP2 of high electric conductivity, a signal transfer speed between the core/peripheral circuit lines 22a and the cell circuit lines 12a may be increased. This may make it possible to improve the electrical characteristics of the semiconductor device.

In an example embodiment, the contact connection pattern CP may not be provided.

The memory cell layer 110 may further include an interconnection pattern WP. The interconnection pattern WP may be disposed on the second interlayer insulating pattern ILD. The interconnection pattern WP may be horizontally spaced apart from the capacitor CAP and the contact connection pattern CP. The interconnection pattern WP may be a line-shaped pattern that is horizontally extended. The interconnection pattern WP may be an element for horizontal interconnection. The interconnection pattern WP may be covered with the fourth interlayer insulating layer 11c, on the second interlayer insulating pattern ILD. The interconnection pattern WP may include a first interconnection pattern WP1 and a second interconnection pattern WP2.

The first interconnection pattern WP1 may be disposed on the second interlayer insulating pattern ILD. The first interconnection pattern WP1 may be an element that is formed through the same process as that for the top electrode TE. A thickness of the first interconnection pattern WP1 may be equal to a thickness of the top electrode TE. The first interconnection pattern WP1 may be formed of the same material as the top electrode TE. The first interconnection pattern WP1 may include a semiconductor material. For example, the first interconnection pattern WP1 may be formed of or include SiGe or doped poly silicon and may have a single- or multi-layered structure.

The second interconnection pattern WP2 may be disposed on the first interconnection pattern WP1. In other words, the first interconnection pattern WP1 may be interposed between the second interlayer insulating pattern ILD and the second interconnection pattern WP2. The second interconnection pattern WP2 may be an element that is formed through the same process as that for the additional electrode AE. A thickness of the second interconnection pattern WP2 may be equal to a thickness of the additional electrode AE. The second interconnection pattern WP2 may be formed of the same material as the additional electrode AE. An electric conductivity of the second interconnection pattern WP2 may be higher than an electric conductivity of the first interconnection pattern WP1. The second interconnection pattern WP2 may be formed of or include at least one of a metallic material or a conductive metal nitride material. For example, the second interconnection pattern WP2 may be formed of or include at least one of W, WN, Ti, TiN, Ta, or TaN.

The cell interconnection patterns 12a and 12b may be electrically connected to the interconnection pattern WP. For example, a fifth contact 66 may be provided in the cell chip 10. The fifth contact 66 may vertically penetrate the fourth and fifth interlayer insulating layers 11c and 12c, near the capacitor CAP. An end portion of the fifth contact 66 may be coupled to the cell circuit lines 12a in the fifth interlayer insulating layer 12c. An opposite end portion of the fifth contact 66 may be coupled to the interconnection pattern WP (e.g., the second interconnection pattern WP2) in the fourth interlayer insulating layer 11c. The fifth contact 66 may be formed of or include at least one metallic material (e.g., copper (Cu) or tungsten (W)).

A sixth contact 56 may be provided in the cell chip 10. The sixth contact 56 may be provided to vertically penetrate the second interlayer insulating pattern ILD, the cell semiconductor layer 100, the second passivation layer 11d, and the first passivation layer 22d. The sixth contact 56 may be horizontally separated or shifted from the fifth contact 66. An end portion of the sixth contact 56 may be coupled to the core/peripheral circuit lines 22a, in the second interlayer insulating layer 22c. An opposite end portion of the sixth contact 56 may be coupled to the interconnection pattern WP (e.g., the second interconnection pattern WP2), in the fourth interlayer insulating layer 11c. Here, the sixth contact 56 may be provided to penetrate the first interconnection pattern WP1 and may be directly connected to the second interconnection pattern WP2. The sixth contact 56 may be formed of or include at least one metallic material (e.g., copper (Cu) or tungsten (W)).

The interconnection pattern WP may be an intermediate interconnection line that is used to connect the sixth contact 56, which is connected to the core/peripheral circuit lines 22a in the core/peripheral chip 20, to the fifth contact 66, which is connected to the cell circuit lines 12a in the cell chip 10.

According to an example embodiment of the inventive concepts, because the fifth contact 66 and the sixth contact 56 are connected to each other through the second interconnection pattern WP2 of high electric conductivity, a signal transfer speed between the core/peripheral circuit lines 22a and the cell circuit lines 12a may be increased. This may make it possible to improve the electrical characteristics of the semiconductor device.

In an example embodiment, the interconnection pattern WP may not be provided.

Although not shown, chip pads may be provided in the cell chip 10 or the core/peripheral chip 20. In an example embodiment, the first chip pads may be provided on a top surface of the fifth interlayer insulating layer 12c of the cell chip 10. The first chip pads may penetrate the fifth interlayer insulating layer 12c and may be coupled to the cell circuit lines 12a. In an example embodiment, second chip pads may be provided on a bottom surface of the third interlayer insulating layer 23c of the core/peripheral chip 20. The second chip pads may be provided to penetrate the third interlayer insulating layer 23c and may be coupled to interconnection lines in the rear interconnection layer 23. The first and second chip pads may be formed of or include at least one metallic material (e.g., copper (Cu)).

In the description of the example embodiments to be explained below, an element previously described with reference to FIGS. 4 and 5 may be identified by the same reference number without repeating an overlapping description thereof, for concise description.

FIG. 5 is an enlarged sectional view illustrating a portion ‘A’ of FIG. 4.

FIG. 5 illustrates an example, in which the relative electrodes TE and AE include the top electrode TE and the additional electrode AE that are sequentially stacked on the dielectric layer DI, but example embodiments of the inventive concepts are not limited to this example.

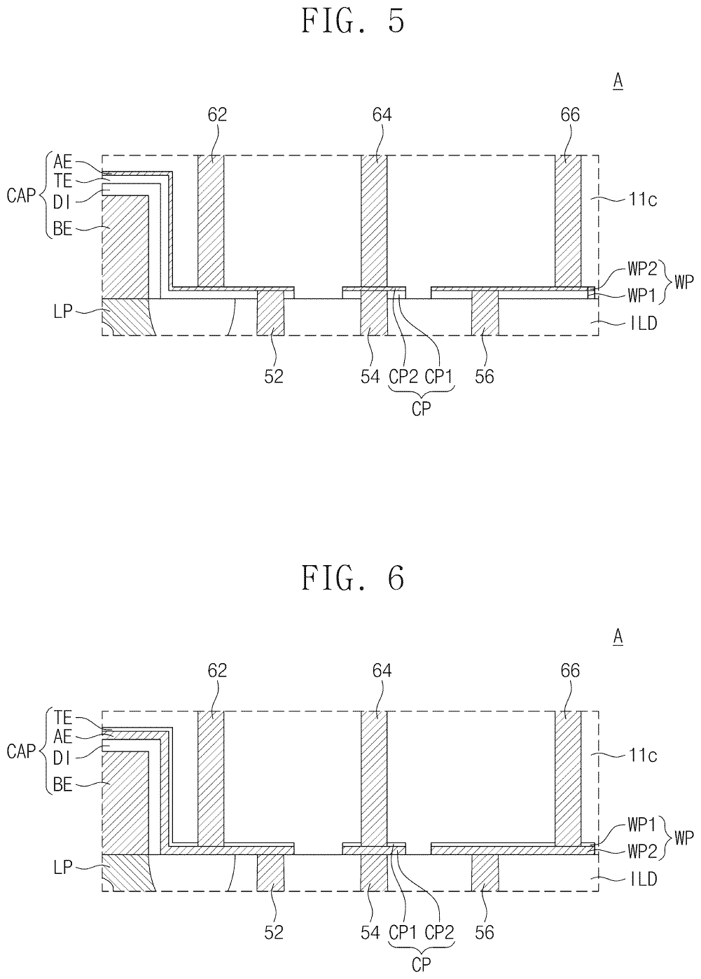

Referring to FIGS. 4 and 6, the additional electrode AE may be disposed on the dielectric layer DI. The additional electrode AE may conformally cover the dielectric layer DI. The additional electrode AE may cover the dielectric layer DI with a uniform thickness. The additional electrode AE may be formed of or include at least one of a metallic material or a conductive metal nitride material.

The top electrode TE may be disposed on the additional electrode AE. The top electrode TE may conformally cover the additional electrode AE. In other words, the additional electrode AE may be interposed between the dielectric layer DI and the top electrode TE. An electric conductivity of the additional electrode AE may be higher than an electric conductivity of the top electrode TE. The top electrode TE may include a semiconductor material.

The first contact 62 may vertically penetrate the fourth and fifth interlayer insulating layers 11c and 12c, on the capacitor CAP or near the capacitor CAP. The first contact 62 may be coupled to the additional electrode AE of the capacitor CAP in the fourth interlayer insulating layer 11c. Here, the first contact 62 may be provided to penetrate the top electrode TE and may be directly connected to the additional electrode AE.

The second contact 52 may be provided to vertically penetrate the second interlayer insulating pattern ILD, the cell semiconductor layer 100, the second passivation layer 11d, and the first passivation layer 22d. The second contact 52 may be coupled to the additional electrode AE of the capacitor CAP in the fourth interlayer insulating layer 11c.

The memory cell layer 110 may further include the contact connection pattern CP. The contact connection pattern CP may include the first contact connection pattern CP1 and the second contact connection pattern CP2.

The second contact connection pattern CP2 may be disposed on the second interlayer insulating pattern ILD. The second contact connection pattern CP2 may be formed of the same material as the additional electrode AE. The second contact connection pattern CP2 may be formed of or include at least one of a metallic material or a conductive metal nitride material.

The first contact connection pattern CP1 may be disposed on the second contact connection pattern CP2. In other words, the second contact connection pattern CP2 may be interposed between the second interlayer insulating pattern ILD and the first contact connection pattern CP1. The second first connection pattern CP1 may be formed of the same material as the top electrode TE. An electric conductivity of the second contact connection pattern CP2 may be higher than an electric conductivity of the first contact connection pattern CP1. The first contact connection pattern CP1 may include a semiconductor material.

The third contact 64 may be provided to vertically penetrate the fourth and fifth interlayer insulating layers 11c and 12c. The third contact 64 may be coupled to the second contact connection pattern CP2, in the fourth interlayer insulating layer 11c. Here, the first contact 62 may be provided to penetrate the first contact connection pattern CP1 and may be directly connected to the second contact connection pattern CP2.

The fourth contact 54 may be provided to vertically penetrate the second interlayer insulating pattern ILD, the cell semiconductor layer 100, the second passivation layer 11d, and the first passivation layer 22d. The fourth contact 54 may be coupled to the second contact connection pattern CP2 in the fourth interlayer insulating layer 11c.

The memory cell layer 110 may further include the interconnection pattern WP. The interconnection pattern WP may include the first interconnection pattern WP1 and the second interconnection pattern WP2.

The second interconnection pattern WP2 may be disposed on the second interlayer insulating pattern ILD. The second interconnection pattern WP2 may be formed of the same material as the additional electrode AE. The second interconnection pattern WP2 may be formed of or include at least one of a metallic material or a conductive metal nitride material.

The first interconnection pattern WP1 may be disposed on the second interconnection pattern WP2. That is, the second interconnection pattern WP2 may be interposed between the second interlayer insulating pattern ILD and the first interconnection pattern WP1. The first interconnection pattern WP1 may be formed of the same material as the top electrode TE. An electric conductivity of the second interconnection pattern WP2 may be higher than an electric conductivity of the first interconnection pattern WP1. The first interconnection pattern WP1 may include a semiconductor material.

The fifth contact 66 may be provided to vertically penetrate the fourth and fifth interlayer insulating layers 11c and 12c. The fifth contact 66 may be coupled to the second interconnection pattern WP2, in the fourth interlayer insulating layer 11c. Here, the fifth contact 66 may be provided to penetrate the first interconnection pattern WP1 and may be directly connected to the second interconnection pattern WP2.

The sixth contact 56 may be provided to vertically penetrate the second interlayer insulating pattern ILD, the cell semiconductor layer 100, the second passivation layer 11d, and the first passivation layer 22d. The sixth contact 56 may be coupled to the second interconnection pattern WP2 in the fourth interlayer insulating layer 11c.

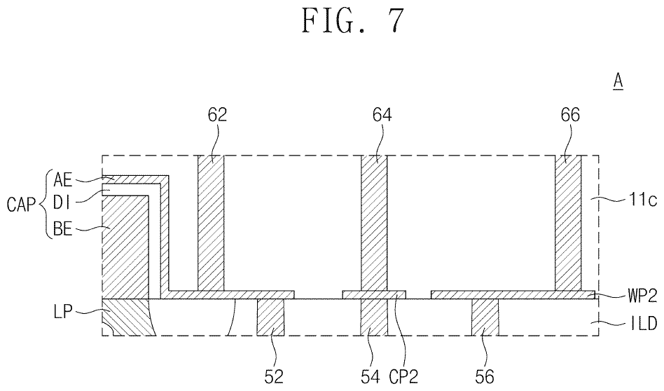

FIG. 7 is an enlarged sectional view illustrating a portion ‘A’ of FIG. 4, according to an example embodiment.

FIGS. 4 and 5 illustrate an example, in which the relative electrode includes both of the top electrode TE and the additional electrode AE, but example embodiments of the inventive concepts are not limited to this example.

Referring to FIGS. 4 and 7, the relative electrode may not include the top electrode TE.

The additional electrode AE may be disposed on the dielectric layer DI. The additional electrode AE may conformally cover the dielectric layer DI. The additional electrode AE may cover a surface of the dielectric layer DI with a uniform thickness. The additional electrode AE may be formed of or include at least one of a metallic material or a conductive metal nitride material.

The capacitor CAP may be covered with the fourth interlayer insulating layer 11c.

The first contact 62 may vertically penetrate the fourth and fifth interlayer insulating layers 11c and 12c, on the capacitor CAP or near the capacitor CAP. The first contact 62 may be coupled to the additional electrode AE of the capacitor CAP, in the fourth interlayer insulating layer 11c. The second contact 52 may be provided to vertically penetrate the second interlayer insulating pattern ILD, the cell semiconductor layer 100, the second passivation layer 11d, and the first passivation layer 22d. The second contact 52 may be coupled to the additional electrode AE of the capacitor CAP in the fourth interlayer insulating layer 11c.

The memory cell layer 110 may further include a contact connection pattern. The contact connection pattern may not include the first contact connection pattern CP1. The contact connection pattern may include the second contact connection pattern CP2.

The second contact connection pattern CP2 may be disposed on the second interlayer insulating pattern ILD. The second contact connection pattern CP2 may be formed of the same material as the additional electrode AE. The second contact connection pattern CP2 may be formed of or include at least one of a metallic material or a conductive metal nitride material.

The third contact 64 may be provided to vertically penetrate the fourth and fifth interlayer insulating layers 11c and 12c. The third contact 64 may be coupled to the second contact connection pattern CP2, in the fourth interlayer insulating layer 11c. The fourth contact 54 may be provided to vertically penetrate the second interlayer insulating pattern ILD, the cell semiconductor layer 100, the second passivation layer 11d, and the first passivation layer 22d. The fourth contact 54 may be coupled to the second contact connection pattern CP2 in the fourth interlayer insulating layer 11c.

The memory cell layer 110 may further include an interconnection pattern. The interconnection pattern may not include the first interconnection pattern WP1. The interconnection pattern may include the second interconnection pattern WP2.

The second interconnection pattern WP2 may be disposed on the second interlayer insulating pattern ILD. The second interconnection pattern WP2 may be formed of the same material as the additional electrode AE. The second interconnection pattern WP2 may be formed of or include at least one of a metallic material or a conductive metal nitride material.

The fifth contact 66 may be provided to vertically penetrate the fourth and fifth interlayer insulating layers 11c and 12c. The fifth contact 66 may be coupled to the second interconnection pattern WP2, in the fourth interlayer insulating layer 11c. The sixth contact 56 may be provided to vertically penetrate the second interlayer insulating pattern ILD, the cell semiconductor layer 100, the second passivation layer 11d, and the first passivation layer 22d. The sixth contact 56 may be coupled to the second interconnection pattern WP2 in the fourth interlayer insulating layer 11c.

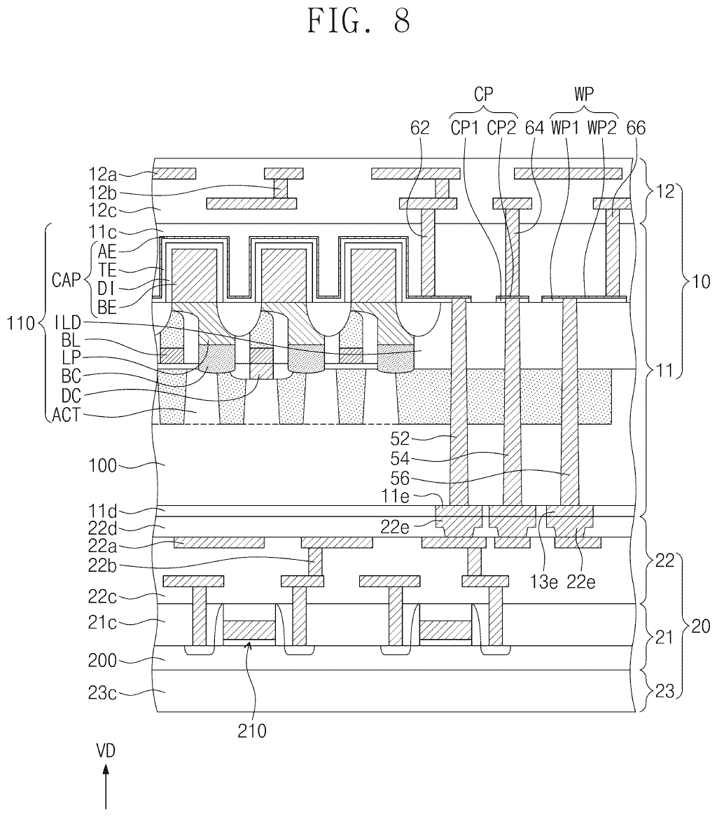

FIG. 8 is a sectional view illustrating a semiconductor device according to an example embodiment of the inventive concepts.

Referring to FIG. 8, the core/peripheral interconnection layer 22 of the core/peripheral chip 20 may further include first internal pads 22e, which are provided in the first passivation layer 22d, compared with the semiconductor device of FIG. 4. The first internal pads 22e may be provided to vertically penetrate the first passivation layer 22d and may be coupled to the core/peripheral circuit lines 22a. The first internal pads 22e may be exposed to the outside through a top surface of the first passivation layer 22d. Here, the top surface of the first passivation layer 22d and a top surface of the first internal pads 22e may be substantially flat and may be substantially coplanar with each other. The first internal pads 22e may be formed of or include at least one metallic material (e.g., copper (Cu)).

The data storage layer 11 of the cell chip 10 may further include second internal pads 11e provided in the second passivation layer 11d. The second, fourth, and sixth contacts 52, 54, and 56 may be provided to penetrate the cell semiconductor layer 100 and may be coupled to the second internal pads 11e. The second internal pads 11e may be exposed to the outside through a bottom surface of the second passivation layer 11d. Here, the bottom surface of the second passivation layer 11d and bottom surfaces of the second internal pads 11e may be substantially flat and may be substantially coplanar with each other. The second internal pads 11e may be formed of or include at least one metallic material (e.g., copper (Cu)).

The cell chip 10 may be disposed on the core/peripheral chip 20. The cell chip 10 may be in direct contact with the core/peripheral chip 20. The cell chip 10 may be provided such that the second internal pads 11e face the core/peripheral chip 20. The second internal pads 11e of the cell chip 10 may be vertically aligned to the first internal pads 22e of the core/peripheral chip 20. The cell chip 10 and the core/peripheral chip 20 may be in contact with each other.

The cell chip 10 and the core/peripheral chip 20 may be connected to each other. For example, the cell chip 10 may be in contact with the core/peripheral chip 20. At the interface between the cell chip 10 and the core/peripheral chip 20, the second internal pads 11e of the cell chip 10 may be bonded to the first internal pads 22e of the core/peripheral chip 20. For example, the first internal pads 22e and the second internal pads 11e may form an intermetal hybrid bonding structure. For example, the first internal pads 22e and the second internal pads 11e, which are bonded to each other, may have a continuous structure, and there may be no visible interface between the first internal pads 22e and the second internal pads 11e. In other words, a respective one of the first internal pads 22e and a corresponding one of the second internal pads 11e may be provided as a single object (e.g., an integral body).

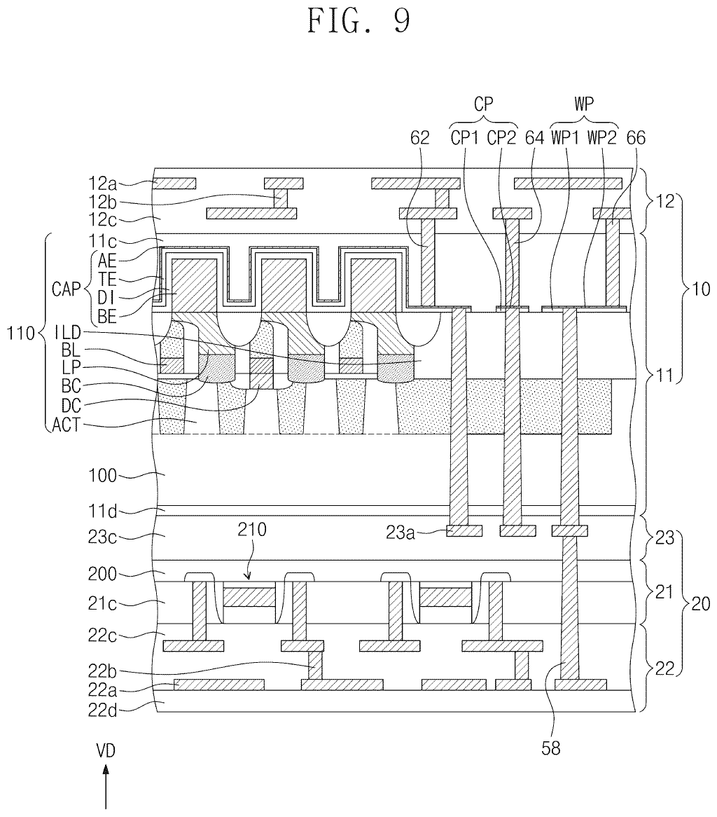

FIG. 9 is a sectional view illustrating a semiconductor device according to an example embodiment of the inventive concepts.

Referring to FIG. 9, the core/peripheral chip 20 may have a structure, in which the core/peripheral interconnection layer 22, the driving layer 21, and the rear interconnection layer 23 are sequentially stacked. For example, the core/peripheral chip 20 of FIG. 9 may have an inverted structure of the core/peripheral chip 20 of FIG. 4. The core/peripheral chip 20 may be provided such that the rear interconnection layer 23 faces the cell chip 10.

The rear interconnection layer 23 of the core/peripheral chip 20 may further include rear interconnection lines 23a provided in the third interlayer insulating layer 23c. For example, the rear interconnection lines 23a may include interconnection lines for horizontal interconnection. In some example embodiments, the rear interconnection lines 23a may further include interconnection lines for vertical interconnection. The rear interconnection lines 23a may be located between top and bottom surfaces of the third interlayer insulating layer 23c. The rear interconnection lines 23a may be formed of or include, for example, copper (Cu) or tungsten (W).

A seventh contact 58 may be provided in the core/peripheral chip 20. The seventh contact 58 may be provided to vertically penetrate the first interlayer insulating layer 21c, the second interlayer insulating layer 22c, and the third interlayer insulating layer 23c. An end portion of the seventh contact 58 may be coupled to the core/peripheral circuit lines 22a in the second interlayer insulating layer 22c. An opposite end portion of the seventh contact 58 may be coupled to the rear interconnection lines 23a in the third interlayer insulating layer 23c.

The cell chip 10 may be disposed on the core/peripheral chip 20. The core/peripheral chip 20 may be in direct contact with the cell chip 10.

At the interface between the cell chip 10 and the core/peripheral chip 20, the second passivation layer 11d of the cell chip 10 may be bonded to the third interlayer insulating layer 23c (interchangeably referred to as “third passivation layer” in this example embodiment) of the core/peripheral chip 20. Here, the second and third passivation layers 11d and 23c may form a hybrid bonding structure of oxide, nitride, or oxynitride. For example, the second and third passivation layers 11d and 23c, which are bonded to each other, may have a continuous structure, and there may be no visible interface between the second and third passivation layers 11d and 23c. For example, the second and third passivation layers 11d and 23c may be formed of the same material, and in this case, there may be no interface between the second and third passivation layers 11d and 23c. In other words, the second and third passivation layers 11d and 23c may be provided as a single object (e.g., a single integral body). For example, the second and third passivation layers 11d and 23c may be bonded to form a single object.

The second, fourth and sixth contacts 52, 54, and 56 of the cell chip 10 may be provided to penetrate the cell semiconductor layer 100, the second passivation layer 11d, and the third interlayer insulating layer 23c and may be coupled to the rear interconnection lines 23a.

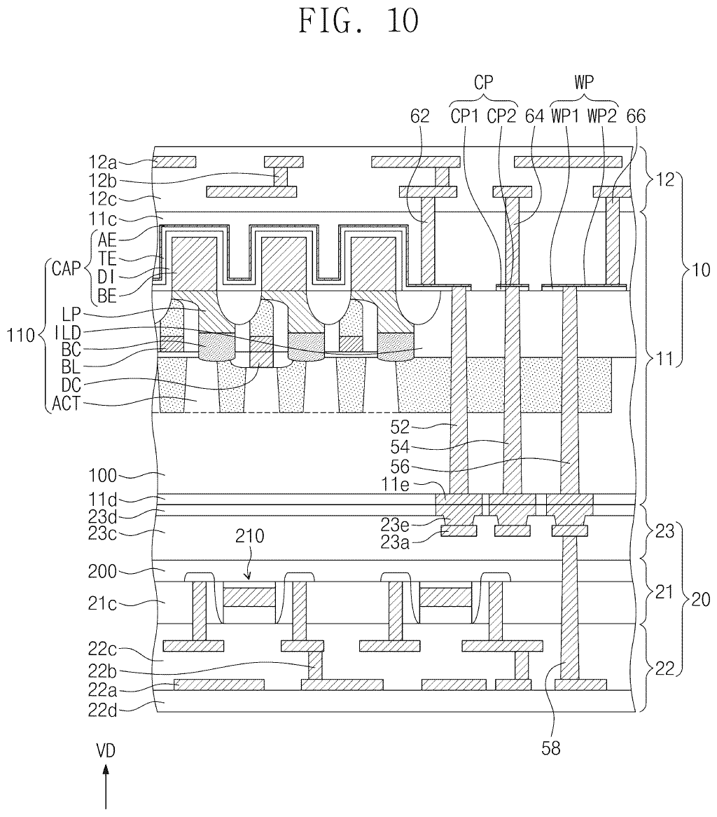

FIG. 10 is a sectional view illustrating a semiconductor device according to an example embodiment of the inventive concepts.

Referring to FIG. 10, the core/peripheral interconnection layer 22 of the core/peripheral chip 20 may further include third internal pads 23e provided on the third interlayer insulating layer 23c, compared with the semiconductor device of FIG. 9. The third internal pads 23e may be provided to vertically penetrate the third interlayer insulating layer 23c and may be coupled to the rear interconnection lines 23a. The third internal pads 23e may be formed of or include at least one metallic material (e.g., copper (Cu)).

A third passivation layer 23d may be disposed on the third interlayer insulating layer 23c. The third passivation layer 23d may cover the third interlayer insulating layer 23c and may enclose the third internal pads 23e. The third internal pads 23e may be exposed to the outside through a top surface of the third passivation layer 23d. Here, the top surface of the third passivation layer 23d and top surfaces of the third internal pads 23e may be substantially flat and may be substantially coplanar with each other. The third passivation layer 23d may be formed of or include at least one of SiO, SiN, SiON, SiCN, or porous insulating materials and may have a single- or multi-layered structure.

The cell chip 10 may be disposed on the core/peripheral chip 20. The cell chip 10 may be in direct contact with the core/peripheral chip 20. The cell chip 10 may be provided such that the second internal pads 11e face the core/peripheral chip 20. The second internal pads 11e of the cell chip 10 may be vertically aligned to the third internal pads 23e of the core/peripheral chip 20. The cell chip 10 and the core/peripheral chip 20 may be in contact with each other.

The cell chip 10 and the core/peripheral chip 20 may be connected to each other. For example, the cell chip 10 may be in contact with the core/peripheral chip 20. At the interface between the cell chip 10 and the core/peripheral chip 20, the second internal pads 11e of the cell chip 10 may be bonded to the third internal pads 23e of the core/peripheral chip 20. For example, the third internal pads 23e and the second internal pads 11e may form an intermetal hybrid bonding structure. For example, the third internal pads 23e and the second internal pads 11e, which are bonded to each other, may have a continuous structure, and there may be no visible interface between the third internal pads 23e and the second internal pads 11e. In other words, a respective one of the third internal pads 23e and a corresponding one of the second internal pads 11e may be provided as a single object (e.g., an integral body).

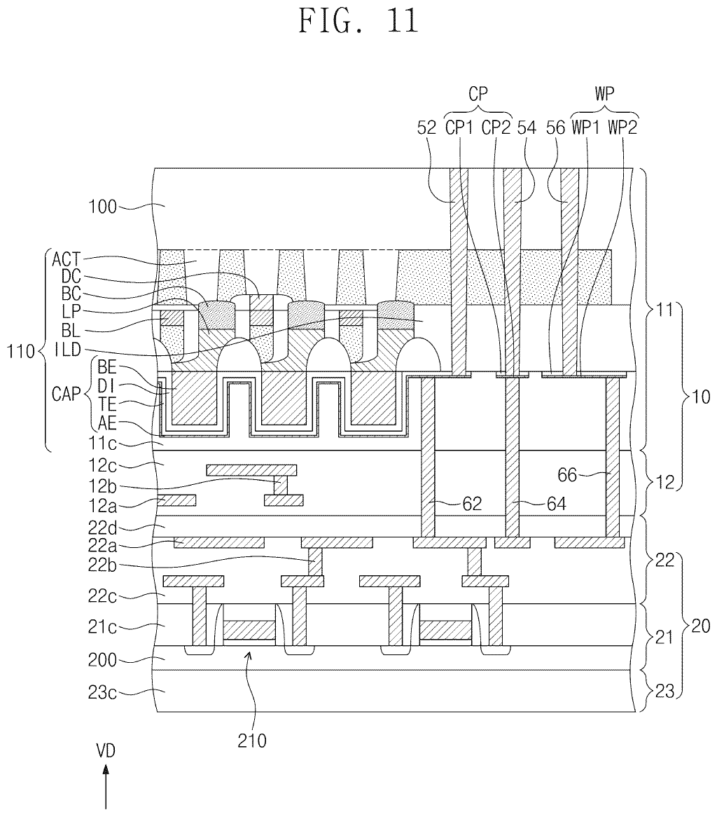

FIG. 11 is a sectional view illustrating a semiconductor device according to an example embodiment of the inventive concepts.

Referring to FIG. 11, the cell chip 10 may have a structure, in which the data storage layer 11 is stacked on the cell interconnection layer 12. For example, the cell chip 10 of FIG. 11 may have an inverted structure of the cell chip 10 of FIG. 4. The cell chip 10 may be provided such that the cell interconnection layer 12 faces the core/peripheral chip 20.

The cell chip 10 may be disposed on the core/peripheral chip 20. The core/peripheral chip 20 may be in direct contact with the cell chip 10.

At the interface between the cell chip 10 and the core/peripheral chip 20, the fifth interlayer insulating layer 12c of the cell chip 10 may be bonded to the first passivation layer 22d of the core/peripheral chip 20. Here, the first passivation layer 22d and the fifth interlayer insulating layer 12c may form a hybrid bonding structure of oxide, nitride, or oxynitride. For example, the first passivation layer 22d and the fifth interlayer insulating layer 12c, which are bonded to each other, may have a continuous structure, and there may be no visible interface between the first passivation layer 22d and the fifth interlayer insulating layer 12c. For example, the first passivation layer 22d and the fifth interlayer insulating layer 12c may be formed of the same material, and in this case, there may be no interface between the first passivation layer 22d and the fifth interlayer insulating layer 12c. In other words, the first passivation layer 22d and the fifth interlayer insulating layer 12c may be provided as a single object (e.g., an integral body). For example, the first passivation layer 22d and the fifth interlayer insulating layer 12c may be bonded to form a single object (e.g., an integral body).

The first, third, and fifth contacts 62, 64, and 66 of the cell chip 10 may be provided to penetrate the fourth interlayer insulating layer 11c, the fifth interlayer insulating layer 12c, and the first passivation layer 22d and may be coupled to the core/peripheral circuit lines 22a.

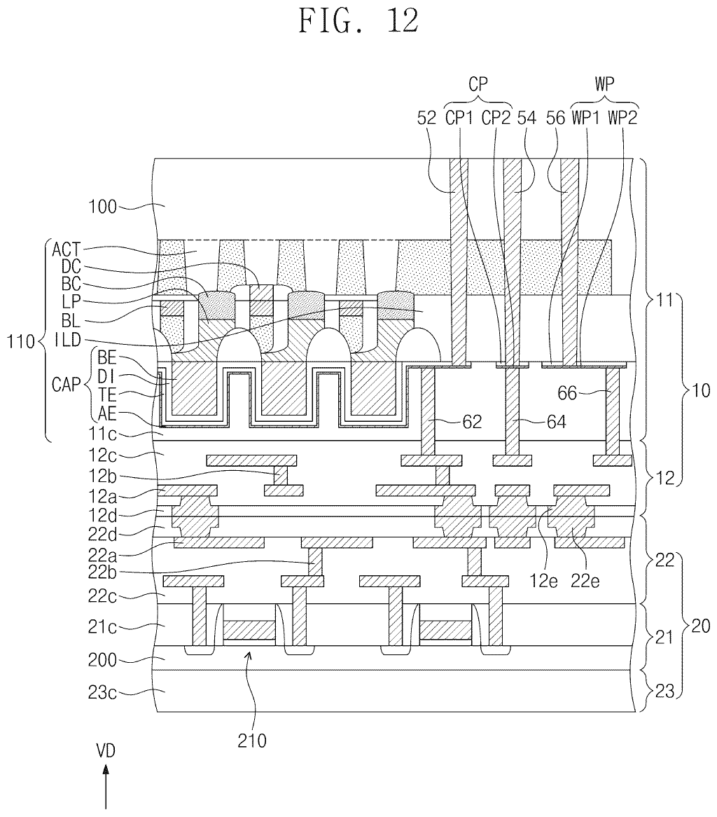

FIG. 12 is a sectional view illustrating a semiconductor device according to an example embodiment of the inventive concepts.

Referring to FIG. 12, the core/peripheral interconnection layer 22 of the core/peripheral chip 20 may further include the first internal pads 22e provided in the first passivation layer 22d, compared with the semiconductor device of FIG. 11. The first internal pads 22e may be provided to vertically penetrate the first passivation layer 22d and may be coupled to the core/peripheral circuit lines 22a. The first internal pads 22e may be exposed to the outside through the top surface of the first passivation layer 22d. Here, the top surface of the first passivation layer 22d and the top surface of the first internal pads 22e may be substantially flat and may be substantially coplanar with each other. The first internal pads 22e may be formed of or include at least one metallic material (e.g., copper (Cu)).

The cell interconnection layer 12 of the cell chip 10 may further include fourth internal pads 12e, which are provided on a bottom surface of the fifth interlayer insulating layer 12c. The fourth internal pads 12e may be provided to vertically penetrate the fifth interlayer insulating layer 12c and may be coupled to the cell circuit lines 12a. The fourth internal pads 12e may be formed of or include at least one metallic material (e.g., copper (Cu)).

A fourth passivation layer 12d may be disposed on the fifth interlayer insulating layer 12c. The fourth passivation layer 12d may be provided to cover the bottom surface of the fifth interlayer insulating layer 12c and to enclose the fourth internal pads 12e. The fourth internal pads 12e may be exposed to the outside through a bottom surface of the fourth passivation layer 12d. Here, the bottom surface of the fourth passivation layer 12d and top surfaces of the fourth internal pads 12e may be substantially flat and may be substantially coplanar with each other. The fourth passivation layer 12d may be formed of or include at least one of SiO, SiN, SiON, SiCN, or porous insulating materials and may have a single- or multi-layered structure.

The cell chip 10 may be disposed on the core/peripheral chip 20. The cell chip 10 may be in direct contact with the core/peripheral chip 20. The cell chip 10 may be provided such that the fourth internal pads 12e faces the core/peripheral chip 20. The fourth internal pads 12e of the cell chip 10 may be vertically aligned to the first internal pads 22e of the core/peripheral chip 20. The cell chip 10 and the core/peripheral chip 20 may be in contact with each other.

The cell chip 10 and the core/peripheral chip 20 may be connected to each other. For example, the cell chip 10 may be in contact with the core/peripheral chip 20. At the interface between the cell chip 10 and the core/peripheral chip 20, the fourth internal pads 12e of the cell chip 10 may be bonded to the first internal pads 22e of the core/peripheral chip 20. For example, the first internal pads 22e and the fourth internal pads 12e may form an intermetal hybrid bonding structure. For example, the first internal pads 22e and the fourth internal pads 12e, which are bonded to each other, may have a continuous structure, and there may be no visible interface between the first internal pads 22e and the fourth internal pads 12e. In other words, a respective one of the first internal pads 22e and a corresponding one of the fourth internal pads 12e may be provided as a single object (e.g., an integral body).

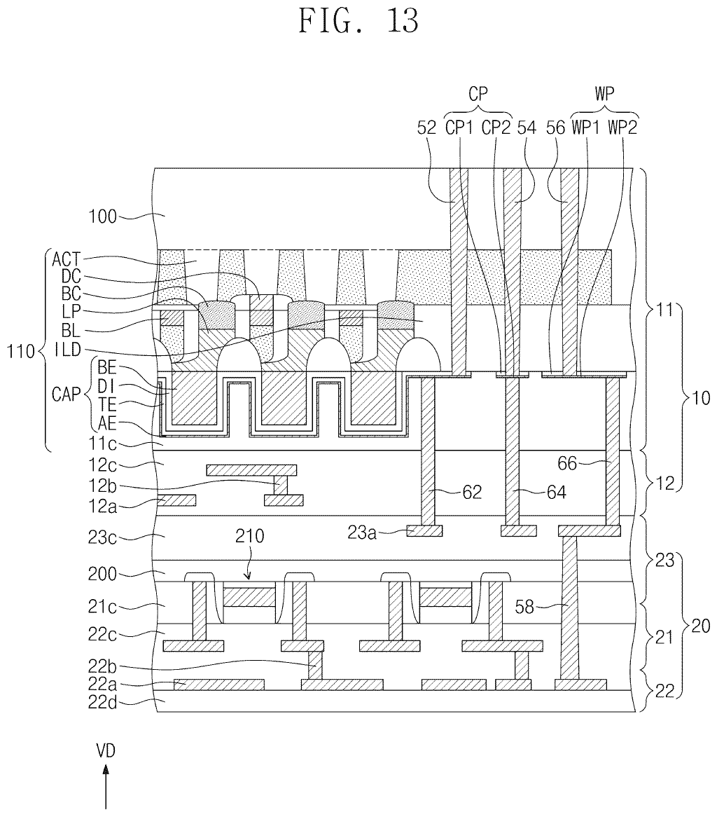

FIG. 13 is a sectional view illustrating a semiconductor device according to an example embodiment of the inventive concepts.

Referring to FIG. 13, the core/peripheral chip 20 may have a structure, in which the core/peripheral interconnection layer 22, the driving layer 21, and the rear interconnection layer 23 are sequentially stacked. For example, the core/peripheral chip 20 of FIG. 13 may have an inverted structure of the core/peripheral chip 20 of FIG. 11. The core/peripheral chip 20 may be provided such that the rear interconnection layer 23 faces the cell chip 10.

The rear interconnection layer 23 of the core/peripheral chip 20 may further include the rear interconnection lines 23a provided in the third interlayer insulating layer 23c. For example, the rear interconnection lines 23a may include interconnection lines for horizontal interconnection.

The cell chip 10 may be disposed on the core/peripheral chip 20. The core/peripheral chip 20 may be in direct contact with the cell chip 10.

At the interface between the cell chip 10 and the core/peripheral chip 20, the fifth interlayer insulating layer 12c of the cell chip 10 may be bonded to the third interlayer insulating layer 23c of the core/peripheral chip 20. Here, the third and fifth interlayer insulating layers 23c and 12c may form a hybrid bonding structure of oxide, nitride, or oxynitride. For example, the third and fifth interlayer insulating layers 23c and 12c, which are bonded to each other, may have a continuous structure, and there may be no visible interface between the third and fifth interlayer insulating layers 23c and 12c. For example, the third and fifth interlayer insulating layers 23c and 12c may be formed of the same material, and in this case, there may be no interface between the third and fifth interlayer insulating layers 23c and 12c. In other words, the third and fifth interlayer insulating layers 23c and 12c may be provided as a single object (e.g., an integral body). For example, the third and fifth interlayer insulating layers 23c and 12c may be bonded to form a single object (e.g., an integral body).

The first, third, and fifth contacts 62, 64, and 66 of the cell chip 10 may be provided to penetrate the fourth interlayer insulating layer 11c, the fifth interlayer insulating layer 12c, and the third interlayer insulating layer 23c and may be electrically connected to the core/peripheral circuit lines 22a.

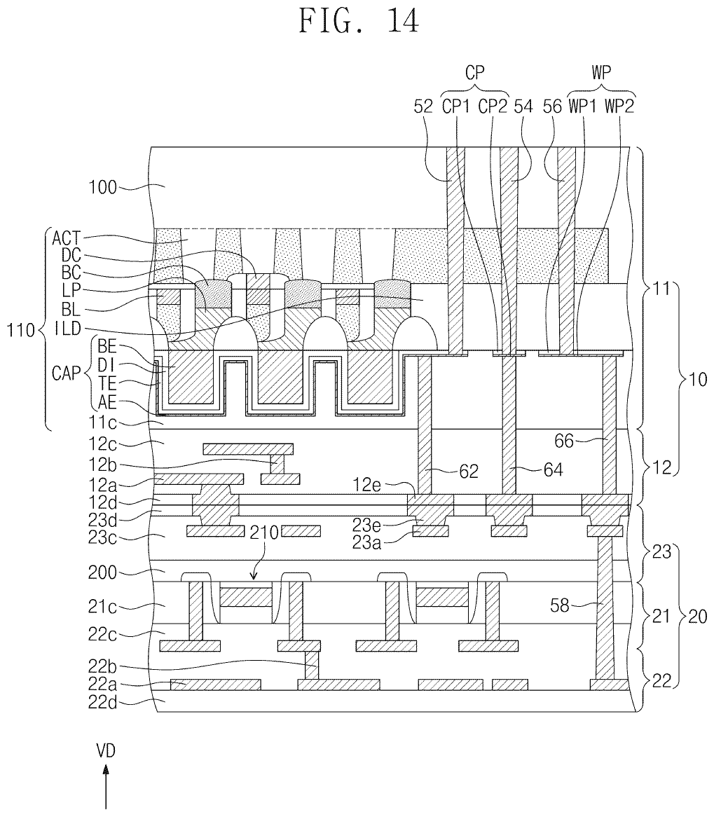

FIG. 14 is a sectional view illustrating a semiconductor device according to an example embodiment of the inventive concepts.

Referring to FIG. 14, the cell interconnection layer 12 of the cell chip 10 may further include the fourth internal pads 12e, which are provided on the bottom surface of the fifth interlayer insulating layer 12c, compared with the semiconductor device of FIG. 13. The fourth internal pads 12e may be provided to vertically penetrate the fifth interlayer insulating layer 12c and may be coupled to the cell circuit lines 12a.

The fourth passivation layer 12d may be disposed on the fifth interlayer insulating layer 12c. The fourth passivation layer 12d may be provided to cover the bottom surface of the fifth interlayer insulating layer 12c and to enclose the fourth internal pads 12e. The bottom surface of the fourth passivation layer 12d and the top surfaces of the fourth internal pads 12e may be substantially flat and may be substantially coplanar with each other.

The core/peripheral interconnection layer 22 of the core/peripheral chip 20 may further include the third internal pads 23e provided on the third interlayer insulating layer 23c. The third internal pads 23e may be provided to vertically penetrate the third interlayer insulating layer 23c and may be coupled to the rear interconnection lines 23a.

The third passivation layer 23d may be disposed on the third interlayer insulating layer 23c. The third passivation layer 23d may cover the third interlayer insulating layer 23c and may enclose the third internal pads 23e. The top surface of the third passivation layer 23d and the top surfaces of the third internal pads 23e may be substantially flat and may be substantially coplanar with each other.

The cell chip 10 may be disposed on the core/peripheral chip 20. The cell chip 10 may be in direct contact with the core/peripheral chip 20. The cell chip 10 may be provided such that the fourth internal pads 12e faces the core/peripheral chip 20. The fourth internal pads 12e of the cell chip 10 may be vertically aligned to the third internal pads 23e of the core/peripheral chip 20. The cell chip 10 and the core/peripheral chip 20 may be in contact with each other.

The cell chip 10 and the core/peripheral chip 20 may be connected to each other. For example, the cell chip 10 may be in contact with the core/peripheral chip 20. At the interface between the cell chip 10 and the core/peripheral chip 20, the fourth internal pads 12e of the cell chip 10 may be bonded to the third internal pads 23e of the core/peripheral chip 20. For example, the third internal pads 23e and the fourth internal pads 12e may form an intermetal hybrid bonding structure. For example, the third internal pads 23e and the fourth internal pads 12e, which are bonded to each other, may have a continuous structure, and there may be no visible interface between the third internal pads 23e and the fourth internal pads 12e. In other words, a respective one of the third internal pads 23e and a corresponding one of the fourth internal pads 12e may be provided as a single object (e.g., an integral body).

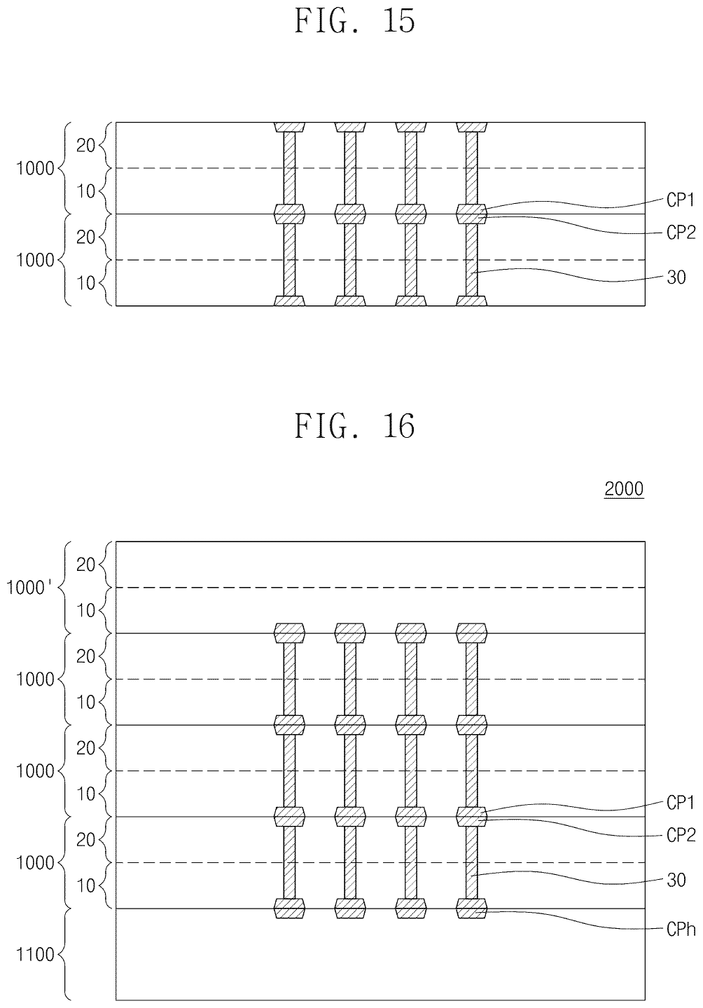

FIG. 15 is a sectional view illustrating a plurality of semiconductor device according to an example embodiment of the inventive concepts.

Referring to FIG. 15, a plurality of memory chips 1000 may be vertically disposed. The memory chips 1000 may be provided to have substantially the same or similar features as the memory chips of FIGS. 4 to 14. Each of the memory chips 1000 may include the cell chip 10 and the core/peripheral chip 20, which are vertically disposed. Each of the cell chip 10 and the core/peripheral chip 20 may include penetration vias 30. The cell chips 10 and the core/peripheral chips 20 may be alternately stacked. FIG. 15 illustrates an example including two memory chips 1000, but example embodiments of the inventive concepts are not limited to this example. For example, three or more memory chips 1000 may be stacked.

The memory chips 1000 may be electrically connected to each other through the penetration vias 30. The penetration vias 30 of the memory chips 1000 may include the penetration vias 30 of the cell chip 10 and the penetration vias 30 of the core/peripheral chip 20. In FIG. 15, the penetration vias 30 of the cell chip 10 are illustrated to be physically connected to the penetration vias 30 of the core/peripheral chip 20, but example embodiments of the inventive concepts are not limited to this example. For example, the penetration vias 30 of the cell chip 10 and the penetration vias 30 of the core/peripheral chip 20 may be connected to each other through an additional contact (not shown) therebetween.

The penetration vias 30 of the pair of the memory chips 1000, which are vertically disposed, may be electrically connected to each other through the first and second contact connection patterns CP1 and CP2. The first and second contact connection patterns CP1 and CP2 may be in contact with each other. Each of the first and second contact connection patterns CP1 and CP2 may be a conductive pad or a conductive bump, independently.

FIG. 16 is a sectional view illustrating a semiconductor package including a semiconductor device according to an example embodiment of the inventive concepts.

Referring to FIG. 16, a semiconductor package 2000 may include a base chip 1100 and a plurality of memory chips 1000 and 1000′ on the base chip 1100. The base chip 1100 may be electrically connected to the memory chips 1000 and 1000′ and may include a host core or a buffer die. The host core may include a processor, which is configured to execute various operations. The buffer die may be configured to receive commands, data, and signals, which are transmitted from the outside, and to send them to the memory chips 1000 and 1000′.

The memory chips 1000 and 1000′ may be electrically connected to the base chip 1100 through the penetration vias 30. As an example, the base chip 1100 may include a base contact pad CPh, which is placed at its uppermost level, and the penetration vias 30 may be connected to the base chip 1100 through the base contact pad CPh. In an example embodiment, the penetration vias 30 may not be provided in the uppermost memory chip 1000′, but example embodiments of the inventive concepts are not limited to this example.

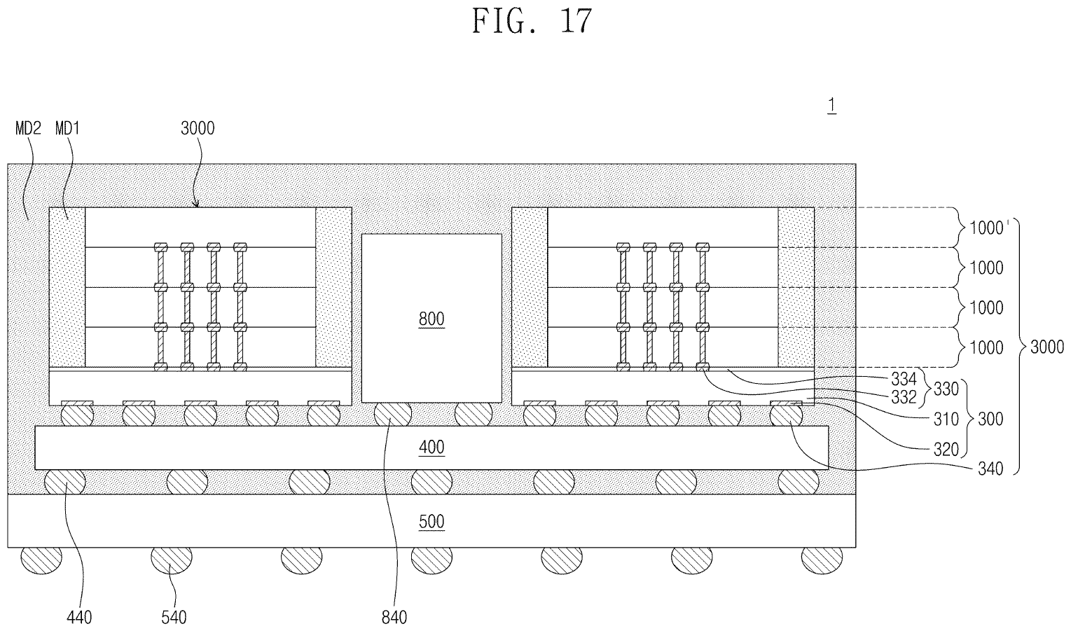

FIG. 17 is a sectional view illustrating a semiconductor package including a semiconductor device according to an example embodiment of the inventive concepts.

Referring to FIG. 17, a semiconductor package 1 may include package substrates 400 and 500, a memory structure 3000, and a host structure 800. The memory structure 3000 and the host structure 800 may be provided on the package substrates 400 and 500 and may be horizontally spaced apart from each other. The memory structure 3000 and the host structure 800 may be electrically connected to each other through the package substrates 400 and 500.

In an example embodiment, the package substrates 400 and 500 may include a first package substrate 400 and a second package substrate 500. The first package substrate 400 may be placed on the second package substrate 500, and the memory structure 3000 and the host structure 800 may be placed on the first package substrate 400. The first package substrate 400 may be an interposer, and the second package substrate 500 may be a printed circuit board (PCB). A first connection terminal 440 may connect the first package substrate 400 electrically to the second package substrate 500. A second connection terminal 540 may be provided to electrically connect the semiconductor package 1 to an external device (e.g., a main board).

The memory structure 3000 may include a base chip 300, the memory chips 1000 and 1000′ on the base chip 300, a first mold layer MD1 enclosing the memory chips 1000 and 1000′, and a memory connection terminal 340 between the base chip 300 and the package substrates 400 and 500. The base chip 300 may correspond to the base chip 1100 of FIG. 16.

The base chip 300 may include a base layer 310, an upper interconnection layer 330 provided on a surface (e.g., a top surface) of the base layer 310, and a lower base pad 320 exposed through an opposite surface (e.g., a bottom surface) of the base layer 310. The upper interconnection layer 330 may include an upper base pad 332 and a base protection layer 334 enclosing the upper base pad 332.

The base chip 300 may be used for redistribution of the memory chips 1000 and 1000′. The upper base pad 332 and the lower base pad 320 may be electrically connected to a circuit line in the base layer 310 and may constitute a redistribution circuit in conjunction with the circuit line. The memory connection terminal 340 may be placed between the lower base pad 320 and the first package substrate 400. The memory connection terminal 340 may include a solder ball or a solder bump. The first mold layer MD1 may include an insulating material. In an example embodiment, the first mold layer MD1 may be formed of or include an epoxy molding compound (EMC).

The host structure 800 may be a data processing device. A host connection terminal 840 may be interposed between the host structure 800 and the first package substrate 400. The host connection terminal 840 may electrically connect the host structure 800 to the first package substrate 400. A second mold layer MD2 on the first package substrate 400 may be provided to enclose the memory structure 3000 and the host structure 800.

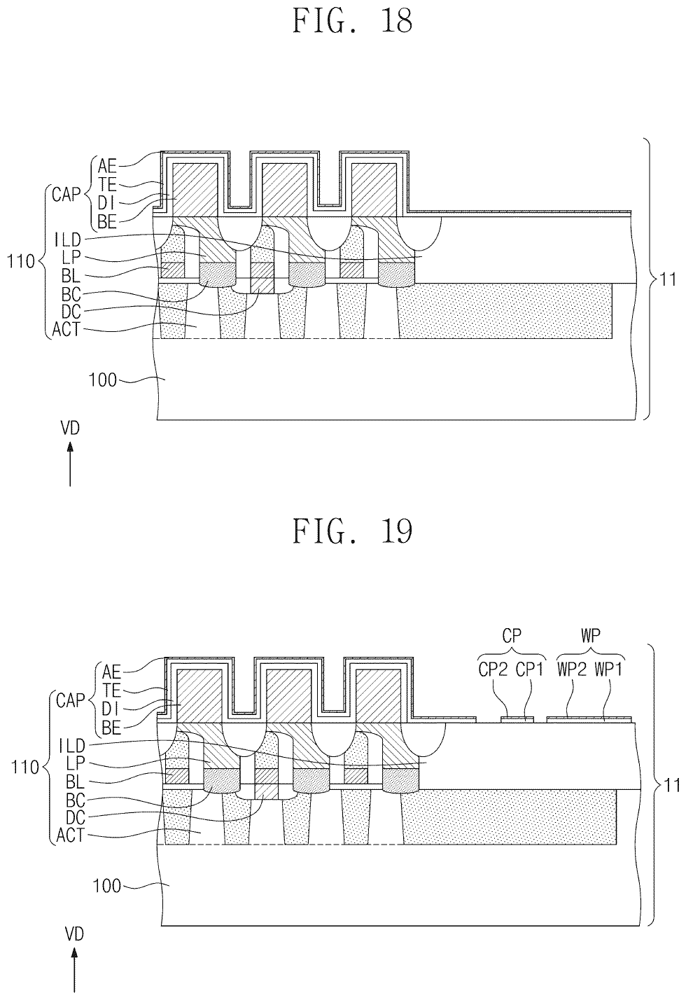

FIGS. 18 to 22 are sectional views illustrating a method of fabricating a semiconductor device according to an example embodiment of the inventive concepts.

Referring to FIG. 18, the data storage layer 11 may be formed. In an example embodiment, the data storage layer 11 may be formed by performing, for example, a conventional process. The data storage layer 11 may include the cell semiconductor layer 100 and the memory cell layer 110. The memory cell layer 110 may include a BCAT-type DRAM device, which includes the active region ACT, the bit line node contact DC, the bit line BL, the storage node contact BC, and the landing pad LP. The second interlayer insulating pattern ILD may be formed on the cell semiconductor layer 100. The second interlayer insulating pattern ILD may be formed to cover or surround the landing pad LP, the storage node contacts BC, the bit lines BL, and the bit line node contact DC, and here, a top surface of the landing pad LP may be exposed to the outside through the top surface of the second interlayer insulating pattern ILD.

The bottom electrodes BE may be formed on the second interlayer insulating pattern ILD. For example, a sacrificial layer may be formed on the second interlayer insulating pattern ILD. The sacrificial layer may be patterned to form penetration holes exposing the landing pads LP. The bottom electrodes BE may be formed by filling the penetration holes with a conductive material. Thereafter, the sacrificial layer may be removed.

The dielectric layer DI may be formed on a front surface of the second interlayer insulating pattern ILD. The dielectric layer DI may be formed on an exposed surface of the bottom electrode BE to have a uniform thickness.

The top electrode TE may be formed on the dielectric layer DI. For example, the top electrode TE may be formed by depositing and coating a conductive material on the front surface of the second interlayer insulating pattern ILD. The top electrode TE may include a semiconductor material. For example, the top electrode TE may be formed of or include SiGe or doped poly silicon and may have a single- or multi-layered structure.

The additional electrode AE may be formed on the top electrode TE. For example, the additional electrode AE may be formed by depositing and coating a conductive material on the front surface of the second interlayer insulating pattern ILD. An electric conductivity of the additional electrode AE may be higher than an electric conductivity of the top electrode TE. The additional electrode AE may be formed of or include at least one of a metallic material or a conductive metal nitride material. For example, the additional electrode AE may be formed of or include at least one of W, WN, Ti, TiN, Ta, or TaN.

The dielectric layer DI, the top electrode TE, and the additional electrode AE, which are stacked on the bottom electrode BE, may constitute the capacitor CAP.

Referring to FIG. 19, a portion of the top electrode TE and a portion of the additional electrode AE, which are placed at a side of the capacitor CAP, may be patterned. The first contact connection pattern CP1 and the first interconnection pattern WP1 may be formed as a result of the patterning of the portion of the top electrode TE, and the second contact connection pattern CP2 and the second interconnection pattern WP2 may be formed as a result of the patterning of the portion of the additional electrode AE.

According to an example embodiment of the inventive concepts, the top electrode of the capacitor CAP may be formed simultaneously with the contact connection pattern CP and the interconnection pattern WP, which are used for interconnection. That is, it may be possible to simplify a process of fabricating a semiconductor device.

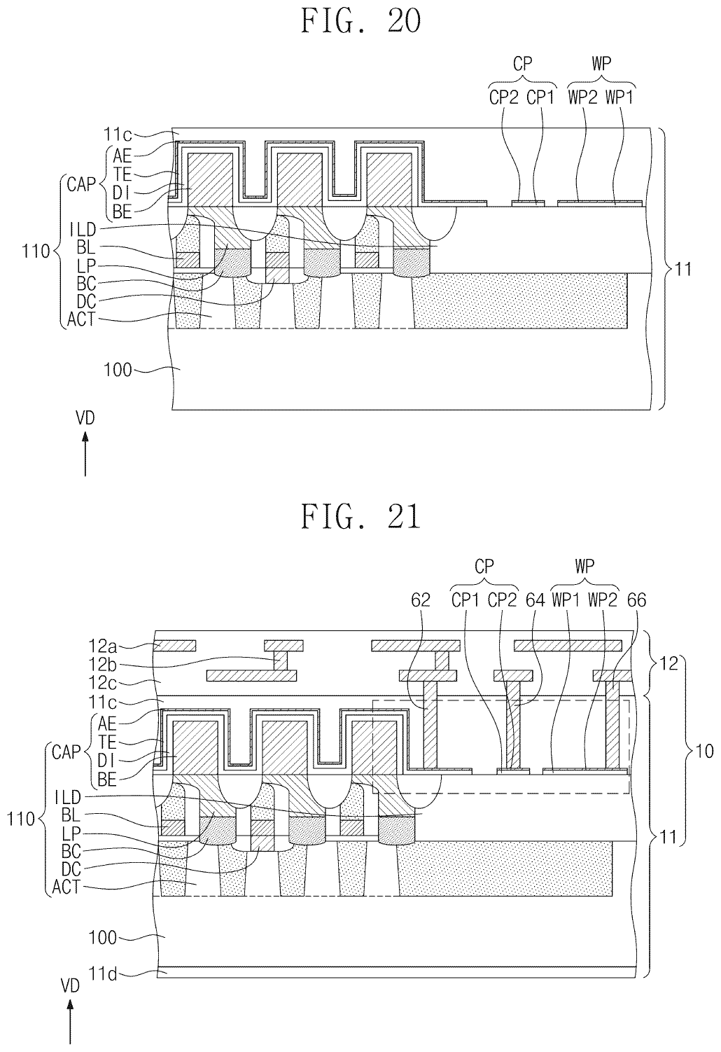

Referring to FIG. 20, the fourth interlayer insulating layer 11c may be formed on the second interlayer insulating pattern ILD. The fourth interlayer insulating layer 11c may cover the capacitor CAP, the contact connection pattern CP, and the interconnection pattern WP.

Referring to FIG. 21, the cell interconnection layer 12 may be formed on the data storage layer 11. For example, the formation of the cell interconnection layer 12 may include repeating steps of depositing and patterning an insulating layer on a top surface of the data storage layer 11 and depositing and patterning a conductive layer, and in an example embodiment, the cell interconnection layer 12 may include the first, third, and fifth contacts 62, 64, and 66 connected to the capacitor CAP, the cell circuit lines 12a, the cell contact plugs 12b electrically connecting the memory cell layer 110 to the cell circuit lines 12a, and the fifth interlayer insulating layer 12c. However, the method of forming the cell interconnection layer 12 is not limited to this example, and the cell interconnection layer 12 may be formed through a conventional method.

The second passivation layer 11d may be formed below the cell semiconductor layer 100.

Although not shown, the second, fourth, and sixth contacts 52, 54, and 56 may be formed to penetrate the second interlayer insulating pattern ILD, the cell semiconductor layer 100, and the second passivation layer 11d and to be connected to the additional electrode AE, the second contact connection pattern CP2 or the second interconnection pattern WP2, respectively, as desired.

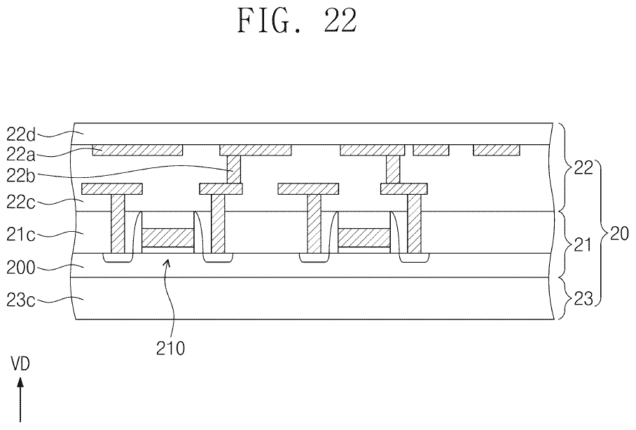

Referring to FIG. 22, the core/peripheral chip 20 may be formed. The core/peripheral chip 20 may be formed by performing, for example, a conventional process. For example, the core/peripheral transistor 210 may be formed on the core/peripheral semiconductor layer 200 by a conventional MOSFET fabrication process. The first interlayer insulating layer 21c may be formed by coating or depositing an insulating material on the front surface of the core/peripheral semiconductor layer 200. The first interlayer insulating layer 21c may cover the core/peripheral transistor 210. The core/peripheral semiconductor layer 200, the core/peripheral transistor 210, and the first interlayer insulating layer 21c may constitute the driving layer 21.

The core/peripheral interconnection layer 22 may be formed on the driving layer 21. For example, processes of depositing and patterning an insulating layer and depositing and patterning a conductive layer may be repeatedly performed on the first interlayer insulating layer 21c. The second interlayer insulating layer 22c may be formed by the patterning of the insulating layer, and the core/peripheral interconnection patterns 22a and 22b may be formed by the patterning of the conductive layer. The first passivation layer 22d may be formed on the second interlayer insulating layer 22c to cover the core/peripheral interconnection patterns 22a and 22b.

The rear interconnection layer 23 may be formed on the rear surface of the core/peripheral semiconductor layer 200. For example, processes of depositing and patterning an insulating layer and depositing and patterning a conductive layer may be repeatedly performed on the rear surface of the core/peripheral semiconductor layer 200.

Referring back to FIG. 4, the cell chip 10 may be bonded to the core/peripheral chip 20. The cell chip 10 may be aligned to the core/peripheral chip 20 such that the second passivation layer 11d faces the first passivation layer 22d. The cell chip 10 may be disposed on the core/peripheral chip 20 such the first and second passivation layers 22d and 11d are in contact with each other. A thermal treatment process may be performed on the first and second passivation layers 22d and 11d. The first and second passivation layers 22d and 11d may be bonded to each other by the thermal treatment process. For example, the first and second passivation layers 22d and 11d may be bonded to form a single object (e.g., an integral body). The bonding of the first and second passivation layers 22d and 11d may be achieved in a natural manner. For example, the first and second passivation layers 22d and 11d may be formed of the same material (e.g., SiO, SiN, or SiON), and the first and second passivation layers 22d and 11d may be bonded to each other by an oxide, nitride, or oxynitride hybrid bonding process, which is caused by a surface activation at an interface between the first and second passivation layers 22d and 11d that are in contact with each other.

In semiconductor devices according to the above example embodiments of the inventive concepts, it may be possible to lower a total electric resistance of a relative electrode of a capacitor. In addition, it may be possible to increase a transmission speed of an electric signal, which is transmitted to each portion of a top electrode along an additional electrode. That is, the semiconductor device with improved electrical characteristics may be provided.

Furthermore, it may be possible to reduce a thickness and an electric resistance of the relative electrode and to reduce a height of a capacitor and a size of a semiconductor device.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While some example embodiments of the inventive concepts have been particularly shown and described, it will be understood by one of ordinary skill in the art that variations in form and detail may be made therein without departing from the spirit and scope of the attached claims.

What is claimed is:

1. A semiconductor device, comprising:
a cell chip; and
a core/peripheral chip on the cell chip,
wherein the cell chip comprises,
a first semiconductor substrate,
a first device layer on the first semiconductor substrate,
a bottom electrode on the first device layer,
a dielectric layer conformally covering a top surface of the first device layer and the bottom electrode,
a top electrode on the bottom electrode and spaced apart from the bottom electrode by the dielectric layer,
an insulating layer on the first device layer and covering the top electrode, and
a first contact vertically penetrating one of the first semiconductor substrate or the insulating layer and connected to the top electrode,
wherein the top electrode comprises a semiconductor layer and a metal layer that are stacked, and
wherein the first contact is in contact with to the metal layer.

2. The semiconductor device of claim 1, wherein
the core/peripheral chip is in contact with a surface of the cell chip that is adjacent to the first device layer, and
the first contact penetrates the insulating layer and is in contact with the metal layer.

3. The semiconductor device of claim 1, wherein
the core/peripheral chip is in contact with a surface of the cell chip that is adjacent to the first semiconductor substrate, and
the first contact penetrates the first semiconductor substrate and is in contact with the metal layer.

4. The semiconductor device of claim 1, wherein
the semiconductor layer conformally covers the dielectric layer, and
the metal layer conformally covers the semiconductor layer.

5. The semiconductor device of claim 1, wherein
the metal layer conformally covers the dielectric layer, and
the semiconductor layer conformally covers the metal layer.

6. The semiconductor device of claim 1, further comprising:
a contact connection pattern on the first device layer and horizontally spaced apart from the bottom electrode, the dielectric layer, and the top electrode;
a second contact vertically penetrating one of the first semiconductor substrate and the insulating layer, the second contact being in contact with the contact connection pattern; and
a third contact provided vertically penetrating the other of the first semiconductor substrate and the insulating layer, the third contact being in contact with the contact connection pattern.

7. The semiconductor device of claim 1, further comprising:
an interconnection pattern on the first device layer, the interconnection pattern being horizontally apart from the bottom electrode, the dielectric layer, and the top electrode, the interconnection pattern being horizontally extended;
a second contact vertically penetrating one of the first semiconductor substrate and the insulating layer, the second contact being in contact with the interconnection pattern; and
a third contact vertically penetrating the other of the first semiconductor substrate and the insulating layer, the third contact being in contact with the interconnection pattern, the third contact being horizontally apart from the second contact in a plan view.

8. The semiconductor device of claim 1, wherein
the semiconductor layer comprises SiGe, and
the metal layer comprises at least one of W, WN, Ti, TiN, Ta, or TaN.

9. The semiconductor device of claim 1, wherein
the first device layer comprises,
a device isolation pattern defining an active region in the first semiconductor substrate,
a word line in the first semiconductor substrate to cross the active region,
a first impurity region in the active region and at one side of the word line,
a second impurity region in the active region and at an opposite side of the word line,
a bit line connected to the first impurity region and crossing the first semiconductor substrate,
a landing pad on the second impurity region, and
a storage node contact connecting the landing pad to the second impurity region, and
the bottom electrode is electrically connected to the landing pad.

10. The semiconductor device of claim 1, wherein
the core/peripheral chip comprises,
a second semiconductor substrate,
a transistor on the second semiconductor substrate, and
an interlayer insulating layer on the second semiconductor substrate to cover the transistor, and
the first contact penetrates the interlayer insulating layer of the core/peripheral chip and is electrically connected to the transistor.

11. A semiconductor device, comprising:
a cell chip; and
a core/peripheral chip on the cell chip,
wherein the cell chip comprises,
a first device layer,
a capacitor on the first device layer,
an insulating layer on the first device layer and covering the capacitor,
a first contact vertically penetrating the first device layer and being in contact with the capacitor,
an interconnection pattern being apart from the capacitor and on the first device layer, and
a second contact vertically penetrating the first device layer and being in contact with the interconnection pattern, wherein the capacitor comprises,
a bottom electrode on a top surface of the first device layer,
a dielectric layer covering the bottom electrode and being on the first device layer,
a top electrode covering the dielectric layer, and
an additional electrode on a surface of the top electrode, the additional electrode having an electric conductivity that is higher than that of the top electrode,
wherein the interconnection pattern comprises,
a first pattern on the top surface of the first device layer, and
a second pattern covering a surface of the first pattern, and
wherein the first pattern comprises a same material as the top electrode, and the second pattern comprises a same material as the additional electrode.

12. The semiconductor device of claim 11, wherein
the top electrode is between the dielectric layer and the additional electrode,
the first pattern is between the first device layer and the second pattern,
the first contact penetrates the top electrode and is in contact with the additional electrode, and
the second contact penetrates the first pattern and is in contact with the second pattern.

13. The semiconductor device of claim 11, wherein
the additional electrode is between the dielectric layer and the top electrode, and
the second pattern is between the first device layer and the first pattern.

14. The semiconductor device of claim 11, further comprising:
a third contact vertically penetrating the insulating layer and being in contact with the second pattern.

15. The semiconductor device of claim 14, wherein the second contact and the third contact are horizontally spaced apart from each other, when viewed in a plan view.

16. The semiconductor device of claim 11, wherein
the top electrode and the first pattern comprise SiGe, and
the additional electrode and the second pattern comprise at least one of W, WN, Ti, TiN, Ta, or TaN.

17. The semiconductor device of claim 11, wherein
a thickness of the top electrode is equal to a thickness of the first pattern, and
a thickness of the additional electrode is equal to a thickness of the second pattern.

18. The semiconductor device of claim 11, wherein
the cell chip further comprises a first semiconductor substrate, and
the first device layer comprises,
a device isolation pattern defining an active region in the first semiconductor substrate,
a word line in the first semiconductor substrate and crossing the active region,
a first impurity region in the active region and at one side of the word line,
a second impurity region in the active region and at an opposite side of the word line,
a bit line connected to the first impurity region and crossing the first semiconductor substrate,
a landing pad on the second impurity region, and
a storage node contact connecting the landing pad to the second impurity region, and
the bottom electrode is electrically connected to the landing pad.

19. The semiconductor device of claim 11, wherein the core/peripheral chip comprises:
a second semiconductor substrate;
a second device layer on the second semiconductor substrate; and
an interlayer insulating layer covering the second device layer,
wherein the first contact penetrated the first device layer and the second device layer and is electrically connected to a transistor in the second device layer.

20. A semiconductor device, comprising:
a first semiconductor substrate;
a device layer on the first semiconductor substrate;
an interlayer insulating layer on the first semiconductor substrate and covering the device layer;
a second semiconductor substrate on the interlayer insulating layer;
a device isolation pattern defining an active region in the second semiconductor substrate;
a word line in the second semiconductor substrate and crossing the active region;
a first impurity region in the active region and at one side of the word line;
a second impurity region in the active region and at an opposite side of the word line;
a bit line connected to the first impurity region and crossing the second semiconductor substrate;
a landing pad on the second impurity region;
a storage node contact connecting the landing pad to the second impurity region;
a capacitor connected to the landing pad; and
a contact vertically penetrating the second semiconductor substrate and the interlayer insulating layer and connecting the device layer to the capacitor,
wherein the capacitor comprises,
a bottom electrode,
a top electrode conformally covering the bottom electrode,
a dielectric layer between the bottom electrode and the top electrode, and
an additional electrode conformally covering the top electrode,
wherein an electric conductivity of the additional electrode is higher than an electric conductivity of the top electrode, and
wherein the contact penetrates the top electrode and is in contact with the additional electrode.
